(19) United States
(12) Patent Application Publication
(10) Pub. No.: US 2025/0280666 A1
(43) Pub. Date: Sep. 4, 2025

(54) Display Device

(71) Applicant: LG Display Co., Ltd., Seoul (KR)

(72) Inventors: JaeHee Park, Paju-si (KR); DongYoon Kim, Paju-si (KR)

(21) Appl. No.: 18/949,647

(22) Filed: Nov. 15, 2024

(30) Foreign Application Priority Data
Feb. 29, 2024 (KR) 10-2024-0030210

(51) Int. Cl. H10K 59/123; H10K 59/121; H10K 59/126; H10K 59/131; H10K 59/80

(52) U.S. Cl. CPC H10K 59/123; H10K 59/1213; H10K 59/126; H10K 59/131; H10K 59/8791

(57) ABSTRACT

Disclosed is a display device comprising first subpixel and the second subpixel disposed adjacent to each other, a first light emitting element disposed in the first subpixel, a second light emitting element disposed in the second subpixel, a first driving transistor configured to supply a driving current to the first light emitting element, a second driving transistor configured to supply a driving current to the second light emitting element and disposed to at least partially overlap the first light emitting element, and a first metal layer disposed between the second driving transistor and the first light emitting element.

### CROSS-REFERENCE TO RELATED APPLICATION

This application claims the benefit of the Republic of Korea Patent Application No. 10-2024-0030210 filed on Feb. 29, 2024, which is hereby incorporated by reference in its entirety.

### BACKGROUND

### Technical Field

The present disclosure relates to a display device.

### Description of the Related art

With the development of information society, the demand for a display device for displaying an image is increasing in various forms. Accordingly, display devices such as a liquid crystal display LCD device, a plasma display panel PDP device, a quantum dot light emitting display QLED device, an organic light emitting display OLED device, and the like are used.

The description provided in the background section should not be assumed to be prior art merely because it is mentioned in or associated with the background section. The background section may include information that describes one or more aspects of the subject technology.

### SUMMARY

In the related art, a display device includes a plurality of subpixels between two substrates confronting each other to display an image. A light emitting element and a circuit element may be disposed in each of the plurality of subpixels. The light emitting element and the circuit element may be disposed on different layers and may overlap in some areas. In the light emitting element and the circuit element, a parasitic capacitance may occur in the overlapping area, whereby it may be difficult to realize a desired luminance due to the increase or decrease in luminance of the subpixel.

In the present disclosure, if an area of a subpixel is reduced to implement high resolution or high transmittance, a circuit element may overlap a light emitting element of an adjacent subpixel. Therefore, the inventors of the present disclosure recognized the limitations mentioned above and other limitations associated with the related art, and conducted various experiments to implement a display device capable of reducing a parasitic capacitance generated between the circuit element and the light emitting element of the adjacent subpixel.

Another aspect of the present disclosure is to provide a display device capable of implementing ESG (Environment/Social/Governance) by reducing the generation of greenhouse gas which may occur due to a manufacturing process.

To achieve these and other aspects of the inventive concepts, as embodied and broadly described herein, a display device may comprise a first subpixel and a second subpixel that are adjacent to each other, a first light emitting element disposed in the first subpixel, a second light emitting element disposed in the second subpixel, a first driving transistor configured to supply a driving current to the first light emitting element, a second driving transistor configured to supply a driving current to the second light emitting element and disposed to at least partially overlap the first light emitting element, and a first metal layer disposed between the second driving transistor and the first light emitting element.

In accordance with another aspect of the present disclosure, there is provided a display device comprising a display area including a transmission area and a non-transmission area, a first light emitting element and a second light emitting element disposed adjacent to each other in the non-transmission area, a first circuit element disposed in the non-transmission area and configured to drive the first light emitting element, and a second circuit element disposed in the non-transmission area and configured to drive the second light emitting element, wherein at least a portion of the second circuit element overlaps the first light emitting element.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the following claims. Nothing in this section should be taken as a limitation on those claims. Further aspects and advantages are discussed below in conjunction with embodiments of the disclosure.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, that may be included to provide a further understanding of the disclosure and may be incorporated in and constitute a part of the disclosure, illustrate embodiments of the disclosure and together with the description serve to explain various principles of the disclosure.

The above and other aspects, features and other advantages of the present disclosure will be more clearly understood from the following detailed description taken in conjunction with the accompanying drawings, in which:

FIG. 1 is a perspective view schematically illustrating a display device according to an example embodiment of the present disclosure;

FIG. 2 is a plan view schematically illustrating a display panel according to an example embodiment of the present disclosure;

FIG. 3 schematically illustrates an example embodiment of a pixel provided in a region A of FIG. 2;

FIG. 4 is a circuit diagram illustrating an example of a circuit element of a subpixel shown in FIG. 3;

FIG. 5 schematically illustrates an example in which a pixel circuit is disposed in a circuit area;

FIG. 6A schematically illustrates an example in which a first metal layer is disposed in a circuit area;

FIG. 6B schematically illustrates an example in which a second metal layer is disposed in a circuit area;

FIG. 7 is a cross-sectional view illustrating an example embodiment along I-I′ of FIGS. 6A and 6B;

FIG. 8 is a cross-sectional view illustrating a parasitic capacitance generated between a light emitting element of an adjacent subpixel and a pixel circuit when first and second metal layers are not provided;

FIG. 9 is a circuit diagram illustrating a parasitic capacitance generated between a light emitting element of an adjacent subpixel and a pixel circuit when first and second metal layers are not provided;

FIG. 10 is a circuit diagram illustrating a parasitic capacitance generated between a light emitting element of an adjacent subpixel and a pixel circuit when first and/or second metal layers are provided;

FIG. 11 schematically illustrates another example in which a first metal layer is disposed in a circuit area;

FIG. 12 schematically illustrates an example in which a shield layer is disposed in a circuit area;

FIG. 13 schematically illustrates another example embodiment of a pixel provided in a region A of FIG. 2;

FIG. 14 schematically illustrates an example in which a pixel circuit is disposed in a circuit area of FIG. 13;

FIG. 15 schematically illustrates an example in which a transmission area is reduced in size according to a pixel circuit arrangement;

FIG. 16A schematically illustrates an example in which a first metal layer is disposed in a circuit area of FIG. 13;

FIG. 16B schematically illustrates an example in which a second metal layer is disposed in a circuit area of FIG. 13;

FIG. 17 is a cross-sectional view illustrating an example embodiment along II-II′ of FIGS. 16A and 16B;

FIG. 18 schematically illustrates another example in which a first metal layer is disposed in a circuit area of FIG. 13;

FIG. 19 is a graph showing a driving current increase rate according to a driving voltage of an adjacent subpixel when a first metal layer and/or a second metal layer are not provided; and

FIG. 20 is a graph showing a driving current increase rate according to a driving voltage of an adjacent subpixel when a first metal layer and/or a second metal layer are provided.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to embodiments of the present disclosure, examples of which may be illustrated in the accompanying drawings. In the following description, when a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and may be changed as is known in the art, with the exception of steps and/or operations necessarily occurring in a particular order. Like reference numerals designate like elements throughout. Names of the respective elements used in the following explanations may be selected only for convenience of writing the specification and may be thus different from those used in actual products.

Advantages and features of the present disclosure, and implementation methods thereof will be clarified through the following example embodiments, described with reference to the accompanying drawings. The present disclosure may, however, be embodied in different forms and should not be construed as being limited to the example embodiments set forth herein. Rather, these example embodiments are provided so that this disclosure will be thorough and complete, and will fully convey the scope of the present disclosure to those skilled in the art.

The shapes, sizes, areas, ratios, angles, and numbers disclosed in the drawings for describing example embodiments of the present disclosure are merely examples, and thus the present disclosure is not limited to the illustrated details. Like reference numerals refer to like elements throughout. In the following description, when the detailed description of the relevant known function or configuration is determined to unnecessarily obscure the important point of the present disclosure, the detailed description will be omitted or briefly provided. In the case in which “comprise,” “have,” “include”, and “consist of” described in the present specification are used, another part may also be present unless “only” is used. The terms in a singular form may include plural forms unless noted to the contrary. Any implementation described herein as an “example” is not necessarily to be construed as preferred or advantageous over other implementations.

In construing an element, the element is construed as including an error region or tolerance range although there is no explicit description thereof.

In describing a positional relationship, for example, when the positional order is described using “on,” “over,” “under,” “above,” “below,” “beneath,” “near,” “close to,” or “adjacent to,” “beside,” “next to,” or the like, one or more other parts may be disposed between the two parts unless a more limiting term, such as “immediate(ly),” “direct(ly),” or “close(ly)” is used. For example, when a structure is described as being positioned “on,” “over,” “under,” “above,” “below,” “beneath,” “near,” “close to,” or “adjacent to,” “beside,” or “next to” another structure, this description should be construed as including a case in which the structures contact each other as well as a case in which a third structure is disposed or interposed therebetween. Furthermore, the terms “left,” “right,” “top,” “bottom, “downward,” “upward,” “upper,” “lower,” and the like refer to an arbitrary frame of reference.

In describing a temporal relationship, for example, when the temporal order is described as “after,” “subsequent,” “next,” and “before,” a case which is not continuous may be included, unless a more limiting term, such as “just”, “immediate” or “direct” is used.

It will be understood that, although the terms “first,” “second,” “A,” “B,” “(a),” “(b)” etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. Also, when an element or layer is described as being “connected,” “coupled,” or “adhered” to another element or layer, the element or layer can not only be directly connected, or adhered to that other element or layer, but also be indirectly connected, or adhered to that other another element or layer with one or more intervening elements or layers “disposed” between the elements or layers, unless otherwise specified.

It should be understood that the term “at least one” includes all combinations related with any one item. For example, “at least one among a first element, a second element and a third element” may include all combinations of two or more elements selected from the first, second and third elements as well as each element of the first, second and third elements.

Features of various embodiments of the present disclosure may be partially or overall coupled to or combined with each other, and may be variously inter-operated with each other and driven technically as those skilled in the art can sufficiently understand. The embodiments of the present disclosure may be carried out independently from each other, or may be carried out together in a co-dependent relationship.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

A transistor used in a display device according to exemplary embodiments of the present disclosure may be implemented as any one transistor of an n-channel transistor (NMOS) and a p-channel transistor (PMOS). The transistor may be implemented as an oxide semiconductor transistor having an oxide semiconductor as an active layer or an low temperature poly-silicon (LTPS) transistor having LTPS as the active layer. The transistor may at least include a gate electrode, a source electrode, and a drain electrode. The transistor may be implemented as a thin film transistor (TFT) on a display panel. A carrier in the transistor flows from a source electrode to a drain electrode. In the case of the n-channel transistor (NMOS), since the carrier is an electron, a source voltage may be lower than a drain voltage so that the electron may flow from the source electrode to the drain electrode. In the n-channel transistor (NMOS), a current may flow from the drain electrode to the source electrode, and the source electrode may be an output terminal. In the case of the p-channel transistor (PMOS), since the carrier is a hole, the source voltage may be higher than the drain voltage so that the hole may flow from the source electrode to the drain electrode. Since the hole flows from the source electrode to the drain electrode in the p-channel transistor (PMOS), the current may flow from a source electrode to a drain electrode, and the drain electrode may be the output terminal. Accordingly, it should be noted that since the source and the drain may be changed according to an applied voltage, the source and the drain of the transistor are not fixed. In the present disclosure, a description is made by assuming that the transistor is the n-channel transistor (NMOS), but the present disclosure is not limited thereto, but the p-channel transistor may be used, and as a result, a circuit configuration may also be changed.

Hereinafter, various example embodiments of display device according to the present disclosure will be described in detail with reference to the accompanying drawings. In the drawings, the same or similar elements are denoted by the same reference numerals even though they are depicted in different drawings. Also, in the following description, when the detailed description of the relevant known technology is determined to unnecessarily obscure the important point of the present disclosure, the detailed description will be omitted.

Hereinafter, various example embodiments of the present disclosure will be described in detail with reference to the accompanying drawings.

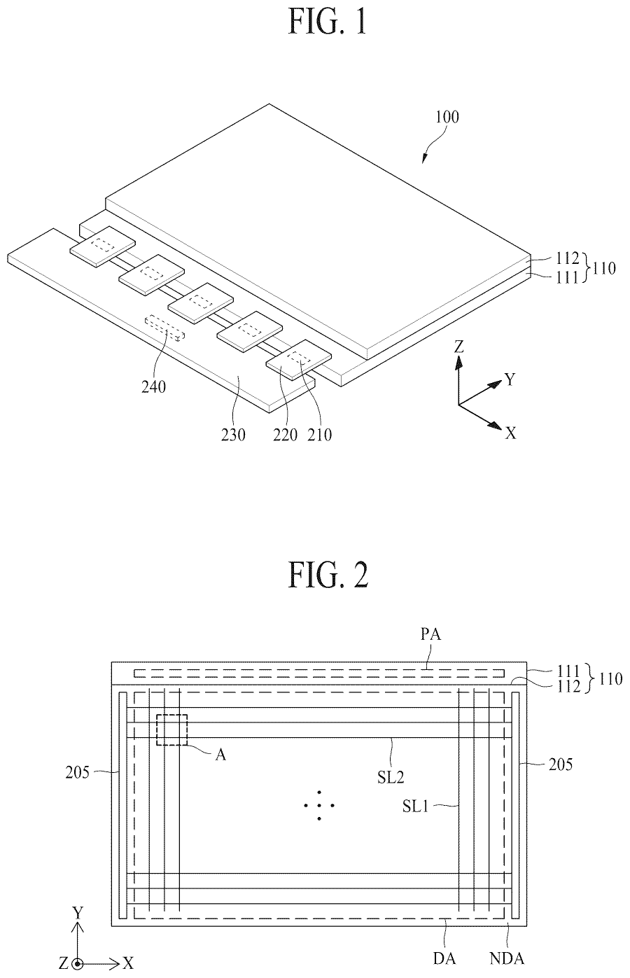

FIG. 1 is a perspective view schematically illustrating a display device according to an embodiment of the present disclosure, and FIG. 2 is a plan view schematically illustrating a display panel according to an embodiment of the present disclosure.

Hereinafter, an X-axis represents a direction parallel to a scan line, a Y-axis represents a direction parallel to a data line, and a Z-axis represents a height direction of a display device 100.

Although the display device 100 according to an embodiment of the present disclosure has been described as an organic light emitting display device, the present disclosure is not limited thereto, and the display device of the present application may be implemented as a liquid crystal display device, a quantum dot light emitting display device, a micro-LED display device, or an electrophoresis display device.

Referring to FIGS. 1 and 2, the display device 100 according to an embodiment of the present disclosure includes a display panel 110, a source drive integrated circuit (hereinafter, referred to as “IC”) 210, a flexible film 220, a circuit board 230, and a timing controller 240.

The display panel 110 includes a first substrate 111 and a second substrate 112 confronting each other. The second substrate 112 may be an encapsulation substrate. The first substrate 111 may be a plastic film, a glass substrate, or a silicon wafer substrate formed using a semiconductor process. The second substrate 112 may be a plastic film, a glass substrate, or an encapsulation film. The first substrate 111 and the second substrate 112 may be formed of a transparent material. For example, the first substrate 111 or the second substrate 112 may include glass, plastic, or a flexible polymer film. For example, the flexible polymer film may be made of any one of polyethylene terephthalate(PET), polycarbonate(PC), acrylonitrile-butadiene-styrene copolymer(ABS), polymethyl methacrylate(PMMA), polyethylene naphthalate(PEN), polyether sulfone(PES), cyclic olefin copolymer(COC), triacetylcellulose(TAC) film, polyvinyl alcohol(PVA) film, polyimide(PI) film, and polystyrene(PS), which is only an example and is not necessarily limited thereto.

The display panel 110 may be divided into a display area DA in which pixels are formed to display an image and a non-display area NDA which is adjacent to the display area DA and does not display an image.

The display area DA may be provided with first signal lines SL1, second signal lines SL2, and pixels, and the non-display area NDA may be provided with a pad area PA in which pads are disposed and at least one scan driver 205.

The first signal lines SL1 may extend in the first direction (e.g., Y-axis direction) and may intersect the second signal lines SL2 in the display area DA. The second signal lines SL2 may extend in the second direction (e.g., X-axis direction) in the display area DA. The pixels are provided in a region where the first signal line SL1 is provided or a region where the first signal line SL1 and the second signal line SL2 intersect each other and emit predetermined light to display an image. The first signal line SL1 may include gate lines, and the second signal line SL2 may include signal lines DL, VDDL, VSSL, and REFL to be describer below.

The plurality of pads may be disposed in the pad area PA. Since the size of the first substrate 111 is larger than the size of the second substrate 112, a portion of the first substrate 111 may be exposed without being covered by the second substrate 112. The pads such as power pads and data pads may be provided on the portion of the first substrate 111 exposed without being covered by the second substrate 112.

The scan driver 205 is connected to the scan line and is configured to supply scan signals thereto. The scan driver 205 may be formed as a gate driver in panel GIP manner in the non-display area NDA on one side or both sides of the display area DA of the display panel 110. Alternatively, the scan driver 205 may be manufactured as a driving chip and may be mounted on the flexible film and may be attached to the non-display area NDA on one side or both sides of the display area DA of the display panel 110 in a tape automated bonding TAB manner.

The source drive IC 210 receives digital video data and a data control signal from the timing controller 240. The source drive IC 210 converts the digital video data into analog data voltages according to the data control signal and supplies the analog data voltages to the data lines. When the source drive IC 210 is manufactured as a driving chip, the source drive IC 210 may be mounted on the flexible film 220 in a chip on film COF or chip on plastic COP method.

Wirings for connecting the pads to the source drive IC 210 and wirings for connecting the pads to wirings of the circuit board 230 may be formed on the flexible film 220. The flexible film 220 may be attached onto the pads using an anisotropic conducting film, whereby the pads and the wirings of the flexible film 220 may be connected to each other.

The circuit board 230 may be attached to the flexible films 220. A plurality of circuits implemented as driving chips may be mounted on the circuit board 230. For example, the timing controller 240 may be mounted on the circuit board 230. The circuit board 230 may be a printed circuit board or a flexible printed circuit board.

The timing controller 240 receives digital video data and a timing signal from an external system board (not shown). The timing controller 240 generates a scan control signal for controlling an operation timing of the scan driver and the data control signal for controlling the source drive ICs 210 based on the timing signal. The timing controller 240 supplies the scan control signal to the scan driver 205 and supplies the data control signal to the source drive ICs 210.

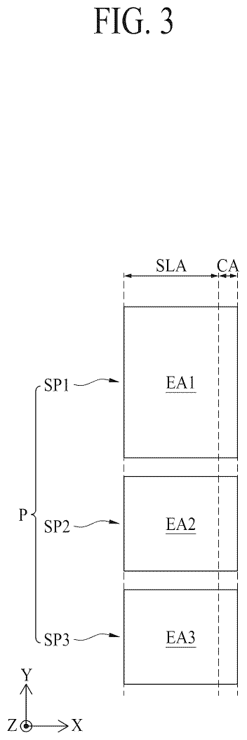

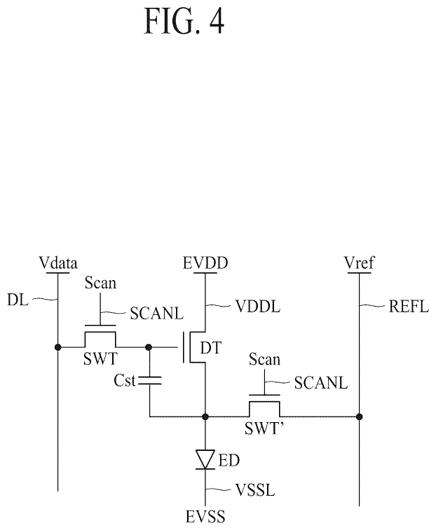

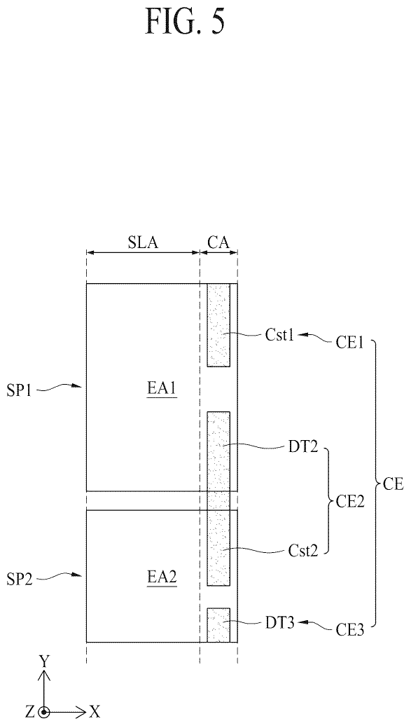

FIG. 3 schematically illustrates an embodiment of a pixel provided in a region A of FIG. 2, FIG. 4 is a circuit diagram illustrating an example of a circuit element of a subpixel shown in FIG. 3, and FIG. 5 schematically illustrates an example in which a pixel circuit is disposed in a circuit area.

The display panel 110 according to an embodiment of the present disclosure may include a display area DA and a non-display area NDA (See FIG. 2). In the display area DA, there are pixels P to display an image.

Referring to FIGS. 3 to 5, each of the pixels P includes a plurality of subpixels SP1, SP2, and SP3. The plurality of subpixels SP1, SP2, and SP3 may be arranged in a matrix form to emit predetermined light to display an image. The plurality of subpixels SP1, SP2, and SP3 may include a plurality of row lines including subpixels SP1, SP2, and SP3 arranged in the first direction (e.g., X-axis direction) and a plurality of column lines including subpixels SP1, SP2, and SP3 arranged in the second direction (e.g., Y-axis direction).

Each of the subpixels SP1, SP2, and SP3 may be any one among a first subpixel SP1 which emits red light, a second subpixel SP2 which emits green light, and a third subpixel SP3 which emits blue light, but not limited thereto. The unit pixel P may include at least two subpixels SP1, SP2, and SP3. For example, as shown in FIG. 3, the unit pixel P may include a first subpixel SP1, a second subpixel SP2, and a third subpixel SP3. The unit pixel P may further include a fourth subpixel for emitting white light. Also, the emitted color, arrangement order and direction of the subpixels SP1, SP2, and SP3 may be variously changed.

Each of the plurality of subpixels SP1, SP2, and SP3 may include a light emitting element for emitting light and a circuit element. In detail, as shown in FIG. 4, each of the plurality of subpixels SP1, SP2, and SP3 may include a circuit element having a 3T(Transistor)1C(Capacitor) structure including a first switching transistor SWT, a second switching transistor SWT′, a driving transistor DT, and a capacitor Cst, and a light emitting element ED, but not limited thereto. Each of the subpixels SP1, SP2, and SP3 may further include a compensation circuit. In this case, various structures such as 4T2C, 5T2C, 6T1C, 6T2C, 7T1C, 7T2C, and the like may be provided, and more or less transistors and capacitors could be included.

Each of the transistors DT, SWT, and SWT′ in each of the subpixels SP1, SP2, and SP3 may include a gate electrode, a source electrode, and a drain electrode. Since the source electrode and the drain electrode are not fixed and may be changed according to a voltage and a current direction applied to the gate electrode, any one of the source electrode and the drain electrode may be referred to as a first electrode, and the other may be represented as a second electrode. The transistors DT, SWT, and SWT′ of each subpixel SP1, SP2, and SP3 may use at least one of polysilicon semiconductor, amorphous silicon semiconductor, and oxide semiconductor. The transistors DT, SWT, and SWT′ may be P-type or N-type transistors, or P-type and N-type transistors may be used interchangeably.

The first switching transistor SWT may supply the data voltage Vdata supplied from the data line DL to the driving transistor DT. In detail, the first switching transistor SWT may charge the capacitor Cst with the data voltage Vdata supplied from the data line DL. In this case, the gate electrode of the first switching transistor SWT may be connected to the scan line SCANL, and the first electrode of the first switching transistor SWT may be connected to the data line DL. In addition, the second electrode of the first switching transistor SWT may be connected to one end of the capacitor Cst, for example, the gate electrode of the driving transistor DT.

The first switching transistor SWT may be turned-on in response to the scan signal Scan applied through the scan line SCANL. When the first switching transistor SWT is turned-on, the data voltage Vdata applied through the data line DL may be transferred to one end of the capacitor Cst.

The second switching transistor SWT′ may supply a reference voltage Vref supplied from a reference line REFL to the driving transistor DT. In detail, the gate electrode of the second switching transistor SWT′ may be connected to the scan line SCANL, and the first electrode of the second switching transistor SWT′ may be connected to the reference line REFL. In addition, the second electrode of the second switching transistor SWT′ may be connected to the second electrode (e.g., the source electrode) of the driving transistor DT and the other end of the capacitor Cst.

The second switching transistor SWT′ may be turned-on in response to the scan signal Scan applied through the scan line SCANL. When the second switching transistor SWT′ is turned-on, the reference voltage Vref applied through the reference line REFL may be transferred to the other end of the capacitor Cst. In addition, the reference voltage Vref may also be applied to the source electrode of the driving transistor DT.

The capacitor Cst may maintain the data voltage Vdata supplied to the driving transistor DT for one frame. Specifically, the first electrode of the capacitor Cst may be connected to the gate electrode of the driving transistor DT, and the second electrode of the capacitor Cst may be connected to the source electrode of the driving transistor DT. The capacitor Cst may be charged with a driving voltage Vgs corresponding to the data voltage Vdata transferred through the first switching transistor SWT, and may supply the charged driving voltage Vgs to the driving transistor DT.

The driving transistor DT may generate a driving current Ids from first power source EVDD supplied from a pixel power line VDDL and may supply the driving current Ids to an anode electrode of the light emitting element ED. Specifically, the gate electrode of the driving transistor DT may be connected to one end of the capacitor Cst, and the first electrode of the driving transistor DT may be connected to the pixel power line VDDL. Also, the second electrode (e.g., the source electrode) of the driving transistor DT may be connected to the anode electrode of the light emitting element ED.

The driving transistor DT may be turned-on according to the driving voltage Vgs charged in the capacitor Cst. When the driving transistor DT is turned-on, the first power source EVDD applied through the pixel power line VDDL may be transferred to the anode electrode of the light emitting element ED. The driving transistor DT may control an emission intensity of the light emitting element ED by controlling the driving current Ids according to the driving voltage Vgs charged in the capacitor Cst.

The light emitting element ED may include the anode electrode connected to the driving transistor DT, a cathode electrode supplied with second power source EVSS from a common power line VSSL, and an emission layer between the anode electrode and the cathode electrode. The anode electrode may be an independent electrode for each light emitting element, and the cathode electrode may be a common electrode shared by all light emitting elements. When the driving current Ids is supplied from the driving transistor DT to the light emitting element ED, electrons from the cathode electrode are injected into the emission layer, and holes from the anode electrode are injected into the emission layer, whereby fluorescent or phosphorescent lights are emitted from the emission layer by recombination of electrons and holes, thereby generating light having brightness proportional to a current value of the driving current.

The anode electrode of the light emitting element ED may be connected to the second electrode of the driving transistor DT, and the cathode electrode of the light emitting element ED may be connected to the common power line VSSL. The light emitting element ED may emit light in response to the driving current Ids generated by the driving transistor DT.

The above-mentioned plurality of subpixels SP1, SP2, and SP3 may include emission areas EA1, EA2, and EA3 in which light emitting elements ED are disposed to emit light. In order to increase an aperture ratio, the display panel 110 may be disposed such that the circuit elements DT, SWT, SWT′, and Cst and the plurality of signal lines DL, VDDL, VSSL, and REFL overlap the emission areas EA1, EA2, and EA3. As shown in FIG. 3, the emission areas may overlap a signal line area SLA in which the plurality of signal lines DL, VDDL, VSSL, and REFL are disposed, and a circuit area CA in which the circuit elements DT, SWT, SWT′, and Cst are disposed.

In this case, the plurality of signal lines DL, VDDL, VSSL, and REFL disposed in the signal line area SLA may include signal lines extending in the second direction (e.g., Y-axis direction). For example, the plurality of signal lines DL, VDDL, VSSL, and REFL may include at least one of the plurality of data lines DL, the reference line REFL, the pixel power line VDDL, and the common power line VSSL which respectively correspond to the plurality of subpixels SP1, SP2, and SP3.

Each of the data lines DL may supply the data voltage to the subpixels SP1, SP2, and SP3. For example, the first data line DL may supply the first data voltage to the first driving transistor of the first subpixel SP1, the second data line DL may supply the second data voltage to the second driving transistor of the second subpixel SP2, and the third data line DL may supply the third data voltage to the third driving transistor of the third subpixel SP3.

The reference line REFL may supply an initialization voltage (or reference voltage) to the driving transistor DT of each of the subpixels SP1, SP2, and SP3 provided in the display area DA.

The pixel power line VDDL may supply first power source to the driving transistor DT of each of the subpixels SP1, SP2, and SP3 provided in the display area DA.

The common power line VSSL may supply second power source to the cathode electrodes of the subpixels SP1, SP2, and SP3 provided in the display area DA. In this case, the second power source may be a common power source commonly supplied to the subpixels SP1, SP2, and SP3.

In each of the plurality of column lines including the subpixels SP1, SP2, and SP3 arranged in the second direction (e.g., Y-axis direction), the plurality of signal lines DL, VDDL, VSSL, and REFL may be disposed to form the signal line area SLA.

The circuit area CA may not overlap the signal line area SL and may be disposed on one side of the signal line area SLA. For example, in the display panel 110 according to an embodiment of the present disclosure, the circuit elements DT, SWT, SWT′ and Cst may be gathered and disposed at one side of the signal line area SLA. The circuit area CA may be disposed in one edge area of each of the subpixels SP1, SP2, and SP3.

In detail, the circuit element CE may include the first switching transistor SWT, the second switching transistor SWT′, the driving transistor DT, and the capacitor Cst, and may be provided for each subpixel SP1, SP2, and SP3. For example, the circuit element may include a first circuit element CE1 connected to the first subpixel SP1 to drive the first subpixel SP1, a second circuit element CE2 connected to the second subpixel SP2 to drive the second subpixel SP2, and a third circuit element CE3 connected to the third subpixel SP3 to drive the third subpixel SP3.

As shown in FIGS. 3 and 5, the plurality of subpixels SP1, SP2, and SP3 may be arranged in a line along the second direction (e.g., Y-axis direction). The circuit elements CE1, CE2, and CE3 for each of the plurality of subpixels SP1, SP2, and SP3 may be arranged in the second direction (e.g., Y-axis direction) along one edge area of each of the plurality of subpixels SP1, SP2, and SP3. At this time, at least some of the circuit elements CE1, CE2, and CE3 may partially overlap with neighboring subpixels SP1, SP2, and SP3 rather than corresponding subpixels SP1, SP2, and SP3.

For example, as shown in FIG. 5, the second subpixel SP2 may include a second circuit element CE2 including a second driving transistor DT2 and a second capacitor Cst2. The second driving transistor DT2 of the second subpixel SP2 may at least partially overlap the neighboring first subpixel SP1. The second driving transistor DT2 of the second subpixel SP2 may at least partially overlap the first light emitting element of the neighboring first subpixel SP1. In addition, the second capacitor Cst2 of the second subpixel SP2 may at least partially overlap the second light emitting element of the corresponding second subpixel SP2.

In the display panel 110 according to an embodiment of the present disclosure, the signal line area SLA and the circuit area CA are disposed not to overlap each other so that it is possible to minimize or reduce an area in which the plurality of signal lines DL, VDDL, VSSL, and REFL and the circuit elements CE1, CE2, and CE3 are formed. If the circuit elements CE1, CE2, and CE3 are disposed between each of the plurality of signal lines DL, VDDL, VSSL, and REFL corresponding to one column line, the circuit elements CE1, CE2, and CE3 may need a space for securing a minimum separation distance from the plurality of signal lines DL, VDDL, VSSL, and REFL on the upper, lower, left, and right sides. Accordingly, the area in which the plurality of signal lines DL, VDDL, VSSL, and REFL and the circuit elements CE1, CE2, and CE3 are formed may increase.

In the display panel 110 according to an embodiment of the present disclosure, the circuit elements CE1, CE2, and CE3 may be gathered and disposed at one side of the signal line area SLA corresponding to one column line, thereby minimizing or reducing a space for separating the circuit elements CE1, CE2, and CE3 and the plurality of signal lines DL, VDDL, VSSL, and REFL.

In addition, in the display panel 110 according to an embodiment of the present disclosure, the circuit elements CE1, CE2, and CE3 corresponding to the plurality of subpixels SP1, SP2, and SP3 may be disposed in the second direction (e.g., Y-axis direction) along one edge area of each of the plurality of subpixels SP1, SP2, and SP3. In this case, some of the circuit elements CE1, CE2, and CE3 may be disposed to overlap the corresponding subpixels SP1, SP2, and SP3. On the other hand, some of the circuit elements CE1, CE2, and CE3 may not be disposed to overlap the corresponding subpixels SP1, SP2, and SP3, and may extend to the adjacent subpixels SP1, SP2, and SP3 and overlap the adjacent subpixels SP1, SP2, and SP3.

As the resolution of the display panel 110 increases, the area of each of the subpixels SP1, SP2, and SP3 is reduced. However, each of the subpixels SP1, SP2, and SP3 may have a minimum area required to arrange the circuit elements CE1, CE2, and CE3 in one edge area. Accordingly, there is a limitation in reducing the area of each of the subpixels SP1, SP2, and SP3, which may be represented by the resolution limit.

The display panel 110 according to an embodiment of the present disclosure may be disposed such that the circuit elements CE1, CE2, and CE3 may partially overlap the area in which the subpixels SP1, SP2, and SP3 are disposed, rather than being disposed to be included in the area in which the corresponding subpixels SP1, SP2, and SP3 are disposed. The display panel 110 according to an embodiment of the present disclosure may efficiently arrange the circuit elements CE1, CE2, and CE3, to thereby minimize or reduce the circuit area CA. Accordingly, the display panel 110 according to an embodiment of the present disclosure may increase the resolution while reducing the area of each of the subpixels SP1, SP2, and SP3.

In the display panel 110 according to an embodiment of the present disclosure, some of the circuit elements CE1, CE2, and CE3 may not be disposed in the area in which the corresponding subpixels SP1, SP2, and SP3 are formed, and some of the circuit elements CE1, CE2, and CE3 may overlap the area in which the subpixels SP1, SP2, and SP3 are formed. The first to third subpixels SP1, SP2, and SP3 may have different areas. Each of the first to third subpixels SP1, SP2, and SP3 may have the different lifespan depending on a material of the emission layer which emits light. In this case, the emission area of each of the first to third subpixels SP1, SP2, and SP3 may be designed to be the same as or different from that of another one of the first to third subpixels SP1, SP2, and SP3 so that the first to third subpixels SP1, SP2, and SP3 have the same or substantially similar lifespan.

At least one of the first to third subpixels SP1, SP2, and SP3 may have a relatively large or relatively small area compared to other subpixels. The circuit elements CE1, CE2, and CE3 corresponding to the subpixels SP1, SP2, and SP3 having the relatively small area may be formed to at least partially overlap the adjacent subpixels SP1, SP2, and SP3 if there is the free space in the adjacent subpixels SP1, SP2, and SP3.

For example, as shown in FIG. 5, the second subpixel SP2 and the third subpixel SP3 may have an area smaller than that of the first subpixel SP1. In this case, the first subpixel SP1 may be a blue subpixel, and the second subpixel SP2 and the third subpixel SP3 may be a red subpixel and a green subpixel, respectively. For example, the red subpixel and the green subpixel may have an area smaller than that of the blue subpixel. A portion of the second circuit element CE2 corresponding to the second subpixel SP2 overlaps the second subpixel SP2, however, another portion of the second circuit element CE2 may not be disposed to overlap the second subpixel SP2 due to the small area of the second subpixel SP2 and may extend to the adjacent first subpixel SP1. For example, the second capacitor Cst2 of the second circuit element CE2 overlaps the second subpixel SP2, however, the second driving transistor DT2 of the second circuit element CE2 may overlap the first subpixel SP1.

In this case, the second driving transistor DT2 of the second circuit element CE2 may overlap the light emitting element of the first subpixel SP1, and a parasitic capacitance may occur between the light emitting element of the first subpixel SP1 and the second driving transistor DT2 of the second circuit element CE2. In the second driving transistor DT2 of the second circuit element CE2, the gate voltage may increase by the parasitic capacitance generated when the adjacent first subpixel SP1 is driven, whereby the luminance of the light emitting element of the second subpixel SP2 connected to the second driving transistor DT2 may increase. A grayscale defect may occur in the second subpixel SP2.

The display panel 110 according to an embodiment of the present disclosure may reduce the parasitic capacitance by disposing a metal layer between the light emitting elements of the adjacent subpixels SP1, SP2, and SP3 and the circuit element CE when the circuit element CE overlaps the adjacent subpixels SP1, SP2, and SP3 instead of the corresponding subpixels SP1, SP2, and SP3.

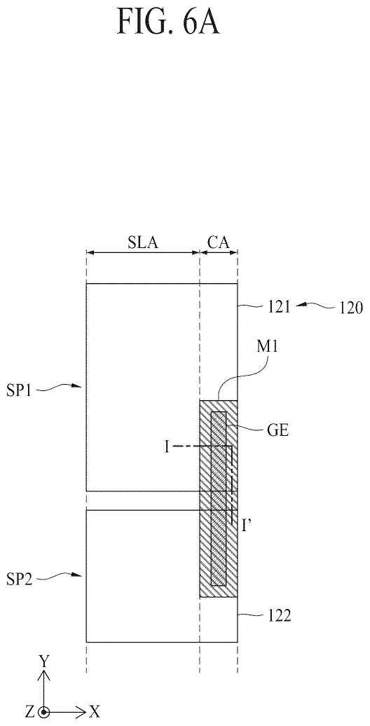

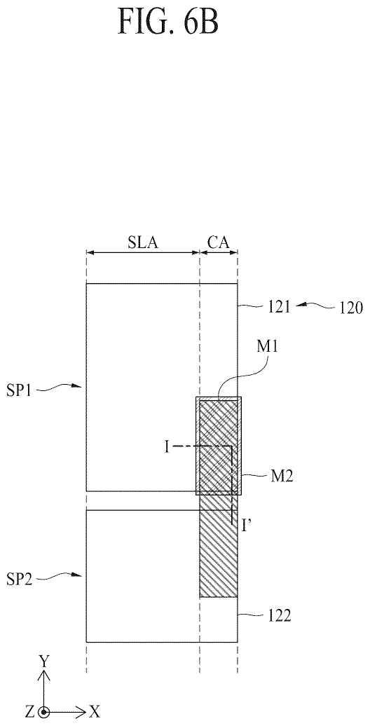

Hereinafter, a structure for reducing the parasitic capacitance generated when the circuit element CE is overlapped with the adjacent subpixels SP1, SP2, and SP3 will be described in more detail with reference to FIGS. 6A to 10.

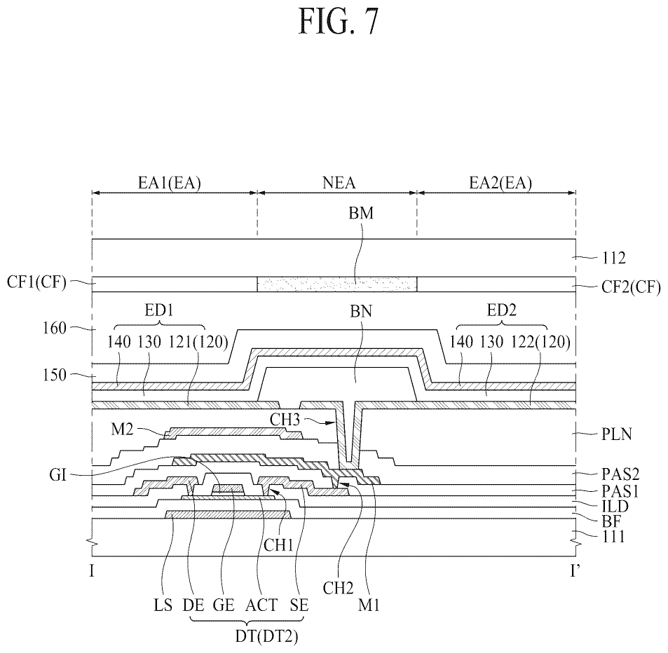

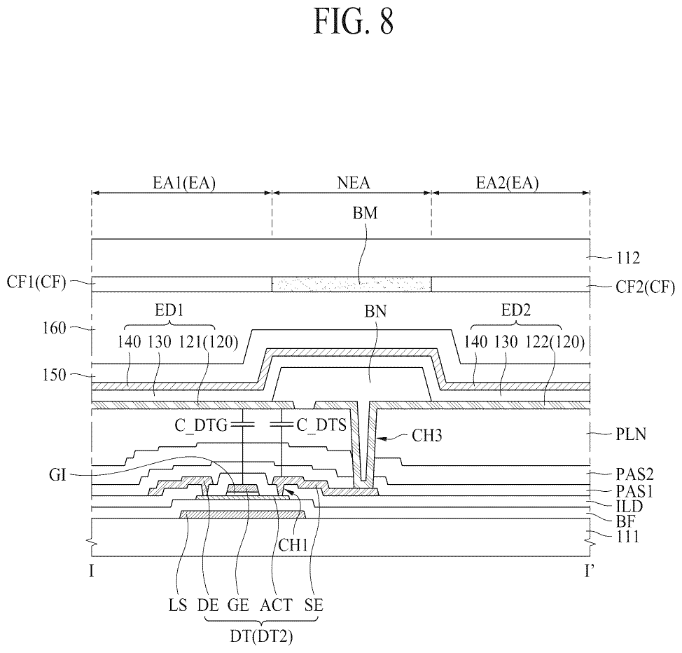

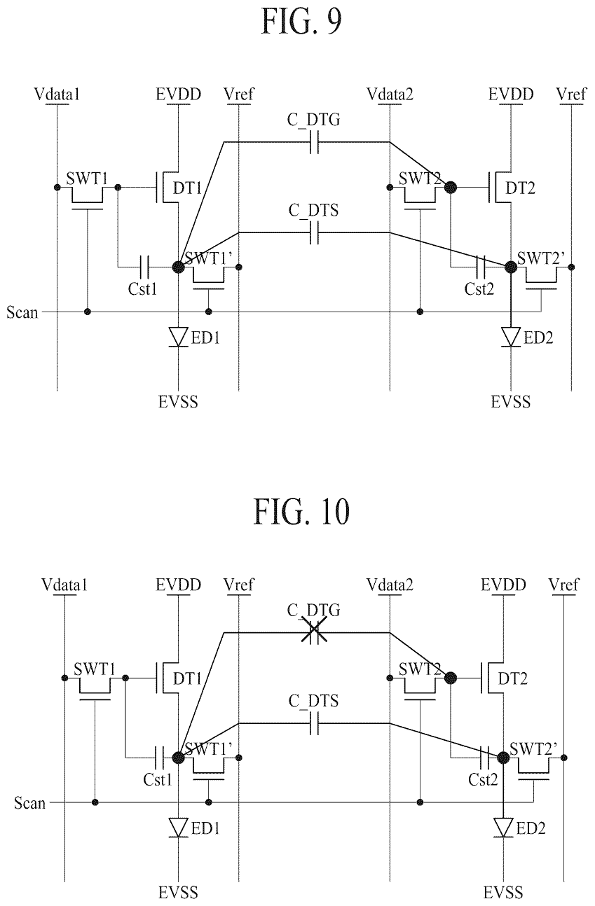

FIG. 6A schematically illustrates an example in which a first metal layer is disposed in the circuit area, FIG. 6B schematically illustrates an example in which a second metal layer is disposed in the circuit area, FIG. 7 is a cross-sectional view illustrating an embodiment along I-I′ of FIGS. 6A and 6B, and FIG. 8 is a cross-sectional view illustrating a parasitic capacitance generated between the light emitting element of the adjacent subpixel and the pixel circuit when the first metal layer and the second metal layer are not provided. FIG. 9 is a circuit diagram illustrating a parasitic capacitance generated between the light emitting element of the adjacent subpixel and the pixel circuit when the first metal layer and the second metal layer are not provided. FIG. 10 is a circuit diagram illustrating a parasitic capacitance generated between the light emitting element of the adjacent subpixel and the pixel circuit when the first metal layer and/or the second metal layer are provided.

In FIGS. 6A to 10, for convenience of description, a portion of the second circuit element CE2 connected to the second subpixel SP2 overlaps the first subpixel SP1, but not limited thereto. The following description may be applied to all cases in which a portion of the pixel circuit connected to one subpixel overlaps another neighboring subpixel.

Referring to FIGS. 5, 6A, 6B, and 7, the second subpixel SP2 may include the second circuit element CE2 including the second driving transistor DT2 and the second capacitor Cst2. The second driving transistor DT2 of the second subpixel SP2 may at least partially overlap the first light emitting element ED1 of the neighboring first subpixel SP1.

In detail, a light shielding layer LS may be provided on a first substrate 111. The light shielding layer LS may be provided in an area where the driving transistor DT is formed to block external light incident on an active layer ACT of the driving transistor DT. The light shielding layer LS may be provided in an area where the second driving transistor DT2 is formed to block external light incident on the active layer ACT. The light shielding layer LS may be formed in a single layer or multiple layers including any one of molybdenum Mo, aluminum Al, chromium Cr, gold Au, titanium Ti, nickel Ni, neodymium Nd, and copper Cu, or an alloy thereof.

A buffer layer BF may be disposed on the light shielding layer LS. The buffer layer BF may be provided to protect the driving transistor DT from impurities such as hydrogen and moisture penetrating through the first substrate 111 vulnerable to moisture permeation. The buffer layer BF may have a single-layered structure or multi-layered structure including an inorganic insulating material such as silicon oxide SiOx, silicon nitride SiNx, and aluminum oxide Al₂O₃.

The driving transistor DT may be disposed on the buffer layer BF. The driving transistor DT may include an active layer ACT, a gate electrode GE, a source electrode SE, and a drain electrode DE disposed on the buffer layer BF.

A gate insulating layer GI may be provided between the active layer ACT and the gate electrode GE. As shown in FIG. 7, the gate insulating layer GI may be patterned only in the area where the gate electrode GE is provided, but not limited thereto. In another embodiment, the gate insulating layer GI may be formed to cover the active layer ACT.

An interlayer insulating layer ILD may be disposed between the gate electrode GE and the source electrode SE/drain electrode DE. The source electrode SE and the drain electrode DE of the second driving transistor DT2 may be connected to a source region and a drain region of the active layer ACT through a first contact hole CH1 penetrating the interlayer insulating layer ILD, respectively.

In addition, one of the source electrode SE and the drain electrode DE of the driving transistor DT may be connected to the light shielding layer LS through a contact hole penetrating through the interlayer insulating layer ILD and the buffer layer BF. The light shielding layer LS may be electrically connected to one of the source electrode SE and the drain electrode DE of the second driving transistor DT2 and may be not operated as a floating gate. When the light shielding layer LS is floated without being connected to other electrodes, a threshold voltage of the driving transistor DT may be changed by the floated light shielding layer LS. The display panel 110 according to an embodiment of the present disclosure may electrically connect the light shielding layer LS to one of the source electrode SE and the drain electrode DE of the driving transistor DT, thereby minimizing or reducing the variation in the threshold voltage of the driving transistor DT.

The active layer ACT may be formed of a silicon-based semiconductor material or an oxide-based semiconductor material. The gate electrode GE, the source electrode SE, and the drain electrode DE may be formed as a single layer or multiple layers including any one of molybdenum Mo, aluminum Al, chromium Cr, gold Au, titanium Ti, nickel Ni, neodymium Nd, and copper Cu, or ITO, and an alloy thereof.

The gate insulating layer GI and the interlayer insulating layer ILD may have a single-layered or multi-layered structure including an inorganic insulating material such as silicon oxide SiOx, silicon nitride SiNx, or aluminum oxide Al₂O₃.

A first insulating layer PAS1 may be provided on the driving transistor DT, and a second insulating layer PAS2 may be provided on the first insulating layer PAS1. The first insulating layer PAS1 and the second insulating layer PAS2 may have a single-layered or multi-layered structure including an inorganic insulating material such as silicon oxide SiOx, silicon nitride SiNx, or aluminum oxide Al₂O₃.

A first metal layer M1 may be provided between the first insulating layer PAS1 and the second insulating layer PAS2. The first metal layer M1 may be disposed on the driving transistor DT and may be provided to cover the gate electrode GE of the driving transistor DT in a plan view. The first metal layer M1 may be electrically connected to one of the source electrode SE and the drain electrode DE of the driving transistor DT. For example, the first metal layer M1 may be electrically connected to the source electrode SE of the driving transistor DT through a second contact hole CH2 penetrating through the first insulating layer PAS1.

A planarization layer PLN for planarizing a step difference due to the driving transistor DT may be provided on the second insulating layer PAS2. The planarization layer PLN may be formed of an organic layer such as acryl resin, epoxy resin, phenolic resin, polyamide resin, polyimide resin, or the like.

A second metal layer M2 may be provided between the second insulating layer PAS2 and the planarization layer PLN. The second metal layer M2 may be disposed on the first metal layer M1 and may be provided to cover a portion of the first metal layer M1 in a plan view. The second metal layer M2 may be provided to cover the area where the first metal layer M1 overlaps the first subpixel SP1. The second metal layer M2 may be in a floating state in which no layer is electrically connected.

The first metal layer M1 and the second metal layer M2 may be formed of a single layer or multiple layers including any one of molybdenum Mo, aluminum Al, chromium Cr, gold Au, titanium Ti, nickel Ni, neodymium Nd, copper Cu, and ITO, or an alloy thereof, but not limited thereto. For example, the first metal layer M1 or the second metal layer M2 may be formed of an alloy of molybdenum Mo and titanium Ti, or a stacked structure of an alloy of molybdenum Mo and titanium Ti, and indium tin oxide ITO.

The light emitting elements ED including a first electrode 120, an emission layer 130, and a second electrode 140 and a bank BN may be provided on the planarization layer PLN.

The first electrode 120 may be provided for each of the subpixels SP1, SP2, and SP3 on the planarization layer PLN. The first electrode 120 may include one first electrode 121 disposed in the first subpixel SP1 and another first electrode 122 disposed in the second subpixel SP2. Although not shown in the drawings, the first electrode 120 may include another first electrode disposed in the third subpixel SP3. The first electrodes 121 and 122 provided for each of the subpixels SP1, SP2, and SP3 may be spaced apart from each other to be electrically insulated from each other.

The first electrode 120 may be electrically connected to the driving transistor DT. For example, as shown in FIG. 7, the first electrode 122 of the second subpixel SP2 may be connected to the first metal layer M1 through a third contact hole CH3 penetrating through the planarization layer PLN and the second insulating layer PAS2. The first metal layer M1 may be connected to one of the source electrode SE and the drain electrode DE of the driving transistor DT through the second contact hole CH2 penetrating through the first insulating layer PAS1. As a result, the first electrode 122 of the second subpixel SP2 may be electrically connected to one of the source electrode SE and the drain electrode DE of the driving transistor DT through the first metal layer M1.

The first electrode 120 may be formed of a metal material having high reflectance, such as a stacked structure Ti/Al/Ti of aluminum and titanium, a stacked structure ITO/Al/ITO of aluminum and ITO, a stacked structure ITO/Ag alloy/ITO of Ag alloy and ITO, MoTi alloy, and a stacked structure ITO/MoTi alloy/ITO of MoTi alloy and ITO. The Ag alloy may be an alloy of silver Ag, palladium Pd, and copper Cu. The MoTi alloy may be an alloy of molybdenum Mo and titanium Ti. The first electrode 120 may be the anode electrode of the light emitting element ED.

The bank BN may be provided on the planarization layer PLN. Also, the bank BN may be provided between the first electrodes 121 and 122. In addition, the bank BN may be formed to cover edges of each of the first electrodes 121 and 122 and to expose a portion of each of the first electrodes 121 and 122. Accordingly, the bank BN may prevent or obviate a current from being concentrated at an end of each of the first electrodes 121 and 122 so that it is possible to prevent or reduce a deterioration of light emitting efficiency.

The bank BN may define the emission area EA of each of the subpixels SP1, SP2, and SP3. The emission area EA of each of the subpixels SP1, SP2, and SP3 is the area in which the first electrode 120, the emission layer 130, and the second electrode 140 are sequentially stacked to allow holes from the first electrode 120 and electrons from the second electrode 140 to be combined with each other in the emission layer 130 to emit light. In this case, since the area where the bank BN is formed does not emit light, the area where the bank BN is formed becomes a non-emission area NEA, and the area where the first electrode 120 is exposed may be an emission area EA.

The bank BN may be formed of an organic layer such as acryl resin, epoxy resin, phenolic resin, polyamide resin, polyimide resin, or the like.

The emission layer 130 may be provided on the first electrode 120. The emission layer 130 may include a hole transporting layer, an emission material layer, and an electron transporting layer. In this case, when a voltage is applied to the first electrode 120 and the second electrode 140, the holes and electrons move to the emission layer through the hole transport layer and the electron transport layer, respectively, and are combined with each other in the emission layer to emit light.

In an embodiment, the emission layer 130 may be a common layer commonly formed in the subpixels SP1, SP2, and SP3. In this case, the emission layer may be a white emission layer for emitting white light.

In another embodiment, the emission layer 130 may include a light emitting material layer formed for each of the subpixels SP1, SP2, and SP3. For example, a red emission layer for emitting red light may be formed in the first subpixel SP1, a green emission layer for emitting green light may be formed in the second subpixel SP2, and a blue emission layer for emitting blue light may be formed in the third subpixel SP3.

The second electrode 140 may be provided on the emission layer 130. The second electrode 140 may be a common layer commonly formed in the subpixels SP1, SP2, and SP3 and configured to apply the same voltage.

The second electrode 140 may be formed of a transparent conductive material capable of transmitting light therethrough such as indium tin oxide ITO and indium zinc oxide IZO, or a semi-transmissive conductive material such as magnesium Mg, silver Ag, or an alloy of magnesium Mg and silver Ag. When the second electrode 140 is formed of a semi-transmissive metal material, a light emission efficiency may be increased by a microcavity. The second electrode 140 may be the cathode electrode of the light emitting element ED.

An encapsulation layer 150 may be provided on the light emitting elements ED. The encapsulation layer 150 may be formed on the second electrode 140 and may be configured to cover the second electrode 140. The encapsulation layer 150 prevents or reduces oxygen or moisture from permeating into the emission layer 130 and the second electrode 140. For example, the encapsulation layer 150 may include at least one inorganic layer, and may further include at least one organic layer. For example, the encapsulating layer 150 may have a structure in which at least one organic layer is disposed between inorganic layers.

A color filter CF may be provided on one surface of a second substrate 112 confronting the first substrate 111. The color filter CF may be patterned for each of the subpixels SP1, SP2, and SP3.

Specifically, the color filter CF may include a first color filter CF1, a second color filter CF2, and a third color filter (not shown). The first color filter CF1 may be disposed to correspond to the emission area EA1 of the first subpixel SP1 and may be a red color filter which transmits red light. The second color filter CF2 may be disposed to correspond to the emission area EA2 of the second subpixel SP2 and may be a green color filter which transmits green light. The third color filter may be disposed to correspond to the emission area EA3 of the third subpixel SP3 and may be a blue color filter which transmits blue light.

A black matrix BM may be provided between the color filters CF. The black matrix BM may be provided between the subpixels SP1, SP2, and SP3 to prevent or reduce color mixing between the subpixels SP1, SP2, and SP3. In addition, the black matrix BM may prevent or reduce light incident from the outside from being reflected to the plurality of signal lines, for example, scan lines, data lines, pixel power lines, common power lines, reference lines, and the like, provided between the subpixels SP1, SP2, and SP3.

The black matrix BM may include a material which absorbs light, for example, black dye which absorbs all light in the visible light wavelength range.

A filler 160 may be provided between the first substrate 111 provided with the light emitting elements ED and the second substrate 112 provided with the color filter CF and the black matrix BM. In this case, the filler 160 may use thermosetting resin or UV-curable resin and may be formed of an organic material having an adhesive property. In an embodiment, the filler 160 may include a material which absorbs hydrogen.

In the display panel 110, the circuit elements CE1, CE2, and CE3 corresponding to the subpixels SP1, SP2, and SP3 having the relatively small area may be formed to at least partially overlap the adjacent subpixels SP1, SP2, and SP3 if there is the free space in the adjacent subpixels SP1, SP2, and SP3. For example, in the display panel 110, the area of the second subpixel SP2 may be smaller than that of the first subpixel SP1. In this case, the display panel 110 may be disposed such that at least a portion of the circuit element CE2 of the second subpixel SP2 overlaps the adjacent first subpixel SP1. As shown in FIG. 8, the display panel 110 may be disposed such that the second driving transistor DT2 of the second subpixel SP2 overlaps the first light emitting element EDI of the first subpixel SP1. In this case, the parasitic capacitance may occur between the second driving transistor DT2 of the second subpixel SP2 and the first light emitting element ED1 of the first subpixel SP1.

In detail, as shown in FIGS. 8 and 9, the first parasitic capacitance C_DTG may be generated between the gate electrode GE of the second driving transistor DT2 and the anode electrode 121 of the first light emitting element ED1. When the first light emitting element ED1 is driven, the voltage of the gate electrode GE of the second driving transistor DT2 may increase by the first parasitic capacitance C_DTG. As the voltage of the gate electrode GE of the second driving transistor DT2 increases, the driving voltage Vgs the second capacitor Cst2 may increase, and furthermore, the driving current Ids supplied to the anode electrode 122 of the second light emitting element ED2 may increase.

Also, as shown in FIGS. 8 and 9, the second parasitic capacitance C_DTS may be generated between the source electrode SE (or drain electrode) of the second driving transistor DT2 and the anode electrode 121 of the first light emitting element ED1. When the first light emitting element ED1 is driven, the voltage of the source electrode SE (or drain electrode) of the second driving transistor DT2 may increase by the second parasitic capacitance C_DTS. As the voltage of the source electrode SE (or drain electrode) of the second driving transistor DT2 increases, the driving voltage Vgs of the second capacitor Cst2 may decrease, and furthermore, the driving current Ids supplied to the anode electrode 122 of the second light emitting element ED2 may decrease.

As described above, when the second driving transistor DT2 of the second subpixel SP2 overlaps the first light emitting element ED1 of the first subpixel SP1, the second driving transistor DT2 may be changed while the driving current Ids supplied to the anode electrode 122 of the second light emitting element ED2 is increased or decreased by the first parasitic capacitance C_DTG and the second parasitic capacitance C_DTS during the driving of the first light emitting element ED1. Accordingly, the second subpixel SP2 may not emit light with a desired luminance while the luminance increases or decreases. For example, a grayscale defect may occur in the second subpixel SP2.

The display panel 110 according to an embodiment of the present disclosure may remove the first parasitic capacitance C_DTG which might occur between the gate electrode GE of the second driving transistor DT2 and the anode electrode 121 of the first light emitting element ED1 by the use of first metal layer M1.

Specifically, in the display panel 110 according to an embodiment of the present disclosure, the first metal layer M1 may be disposed between the second driving transistor DT2 of the second subpixel SP2 and the first light emitting element ED1 of the first subpixel SP1. The first metal layer M1 may be disposed over at least one of the source electrode SE and the drain electrode DE of the second driving transistor DT2 and may be electrically connected to one of the source electrode SE and the drain electrode DE of the second driving transistor DT2. For example, as shown in FIG. 7, the first metal layer M1 may be disposed over the source electrode SE of the second driving transistor DT2 and may be electrically connected to the source electrode SE of the second driving transistor DT2 through the second contact hole CH2. In this case, as shown in FIG. 7, the first metal layer M1 may be formed on the source electrode SE of the second driving transistor DT2 and configured to cover the source electrode SE of the second driving transistor DT2. In addition, although not shown in FIG. 7, the first metal layer M1 may be formed to cover not only the source electrode SE of the second driving transistor DT2 but also the drain electrode DE of the second driving transistor DT2.

The first metal layer M1 may be disposed in the area where the second driving transistor DT2 of the second subpixel SP2 overlaps the first light emitting element ED1 of the first subpixel SP1. The first metal layer M1 may extend from the area where the second light emitting element ED2 of the second subpixel SP2 is overlapped with the first light emitting element ED1 of the first subpixel SP1 and may be electrically connected to the anode electrode 122 of the second light emitting element ED2. The anode electrode 122 of the second light emitting element ED2 may be electrically connected to the source electrode SE of the second driving transistor DT2 through the first metal layer M1.

The first metal layer M1 may be formed to cover the gate electrode GE of the second driving transistor DT2 in the area where the second driving transistor DT2 and the first light emitting element ED1 overlap each other in a plan view. The gate electrode GE of the second driving transistor DT2 may be in a floating state during a period in which the scan signal Scan (See FIG. 4) is not applied. The floating-stated gate electrode GE may be affected by a peripheral signal. Accordingly, when a voltage is applied to the anode electrode 121 of the first light emitting element ED1 disposed over the gate electrode GE of the second driving transistor DT2, the voltage may also be applied to the gate electrode GE in the floating state by the first parasitic capacitance C_DTG generated between the anode electrode 121 of the first light emitting element ED1 and the gate electrode GE of the second driving transistor DT2. Accordingly, the luminance of the second light emitting element ED2 influenced by the voltage level of the gate electrode GE may also increase. In this case, while the voltage is applied to the gate electrode GE to be in the floating state, the second light emitting element ED2 influenced by the voltage level of the gate electrode GE may have the large luminance increase rate compared to the desired luminance.

In the display panel 110 according to an embodiment of the present disclosure, the first metal layer M1 may be disposed between the gate electrode GE of the second driving transistor DT2 and the anode electrode 121 of the first light emitting element ED1, and the first metal layer M1 may be electrically connected to the source electrode SE or the drain electrode DE of the second driving transistor DT2. The source electrode SE or the drain electrode DE of the second driving transistor DT2 may be fixed to the driving voltage Vgs even during a period in which the scan signal Scan (See FIG. 4) is not applied. The first metal layer M1 may be connected to the source electrode SE or the drain electrode DE of the second driving transistor DT2 to be fixed to the driving voltage Vgs. In the display panel 110 according to an embodiment of the present disclosure, as the first metal layer M1, to which the driving voltage Vgs being not in the floating state is applied, is disposed between the gate electrode GE of the second driving transistor DT2 and the anode electrode 121 of the first light emitting element ED1, the first parasitic capacitance C_DTG which might be generated between the anode electrode 121 of the first light emitting element EDI and the gate electrode GE of the second driving transistor DT2 may be removed as shown in FIG. 10.

In addition, as the first metal layer M1 is connected to the source electrode SE or the drain electrode DE of the second driving transistor DT2, the second parasitic capacitance C_DTS may be generated between the anode electrode 121 of the first light emitting element ED1 and the source or drain electrode. However, since the first metal layer M1 is applied with the driving voltage Vgs, the first metal layer M1 may be less affected by the peripheral signal compared to the gate electrode GE. Accordingly, even when a voltage is applied to the anode electrode 121 of the first light emitting element ED1, the driving voltage Vgs is applied to the first metal layer M1, whereby the voltage variation rate in the first metal layer M1 may be small.

Also, the parasitic capacitance may also occur between the gate electrode GE of the second driving transistor DT2 and the first metal layer M1. However, since the first metal layer M1 is applied with the signal or driving voltage Vgs for the same subpixel SP2 as the gate electrode GE of the second driving transistor DT2, the voltage may not be changed when the gate electrode GE of the second driving transistor DT2 is in the floating state. As a result, even when the voltage is applied to the anode electrode 121 of the first light emitting element ED1, the voltage of the gate electrode GE of the second driving transistor DT2 may be not changed in the display panel 110 according to an embodiment of the present disclosure. In addition, the parasitic capacitance occurred between the gate electrode GE of the second driving transistor DT2 and the first metal layer M1 may be a portion of the second capacitor Cst2, which may reduce the forming area of the second capacitor Cst2.

In addition, in the display panel 110 according to an embodiment of the present disclosure, the second metal layer M2 may be disposed between the first metal layer M1 and the first light emitting element ED1 of the first subpixel SP1. The second metal layer M2 may be disposed in the area where the first metal layer M1 overlaps the first light emitting element ED1 of the first subpixel SP1. The second metal layer M2 may be provided to cover the portion of the first metal layer M1, which overlaps the first light emitting element ED1, in a plan view. The second metal layer M2 may be in a floating state in which no layer is electrically connected.

The display panel 110 according to an embodiment of the present disclosure may arrange the second metal layer M2 in the floating state between the first metal layer M1 and the anode electrode 121 of the first light emitting element ED1. In this case, the second metal layer M2 may overlap the first subpixel SP1 and may not overlap the second subpixel SP2. Also, the second metal layer M2 may have a smaller formation area than the area in which the second driving transistor DT2 is disposed. The display panel 110 according to an embodiment of the present disclosure may reduce the second parasitic capacitance C_DTS by the use of the second metal layer M2.

The second metal layer M2 in the floating state may not completely remove the parasitic capacitance between the first metal layer M1 and the anode electrode 121 of the first light emitting element ED1. Herein, since the first metal layer M1 is electrically connected to the source electrode SE or the drain electrode DE of the second driving transistor DT2, the parasitic capacitance may correspond to the second parasitic capacitance C_DTS.

However, since the source electrode SE or the drain electrode DE of the second driving transistor DT2 is fixed to the driving voltage Vgs even during a period in which the scan signal Scan (See FIG. 4) is not applied, the first metal layer M1 may be less affected by the peripheral signal compared to the gate electrode GE in the floating state. When a voltage is applied to the anode electrode 121 of the first light emitting element ED1 disposed over the source electrode SE or the drain electrode DE, the voltage of the source electrode SE or the drain electrode DE of the second driving transistor DT2 connected to the first metal layer M1 may also increase by the second parasitic capacitance C_DTS. However, since the source electrode SE or the drain electrode DE of the second driving transistor DT2 is not in the floating state but in the state being applied with the driving voltage Vgs, the voltage variation rate of the source electrode S or the drain electrode DE may be small compared to the gate electrode GE.

In addition, when the floated second metal layer M2 is disposed between the first metal layer M1 and the anode electrode 121 of the first light emitting element ED1, a third parasitic capacitance may be generated between the first metal layer M1 and the second metal layer M2, and a fourth parasitic capacitance may be generated between the second metal layer M2 and the anode electrode 121 of the first light emitting element ED1. In this case, the third parasitic capacitance and the fourth parasitic capacitance may be connected in series. The second parasitic capacitance C_DTS obtained by synthesizing the third parasitic capacitance and the fourth parasitic capacitance connected in series may be represented as the reciprocal of value obtained by summing the reciprocal of the third parasitic capacitance and the reciprocal of the fourth parasitic capacitance. The second parasitic capacitance C_DTS obtained by synthesizing the third parasitic capacitance and the fourth parasitic capacitance connected in series when the second metal layer M2 is present may be smaller than the second parasitic capacitance C_DTS generated between the first metal layer M1 and the anode electrode 121 of the first light emitting element ED1 when the second metal layer M2 is not present. Therefore, the display panel 110 according to an embodiment of the present disclosure may reduce the second parasitic capacitance C_DTS by the use of the second metal layer M2.

As a result, the display panel 110 according to an embodiment of the present disclosure may remove the first parasitic capacitance C_DTG and may also decrease the second parasitic capacitance C_DTS, thereby overcoming the grayscale defect of the second subpixel SP2 caused by the driving of the adjacent first subpixel SP1.

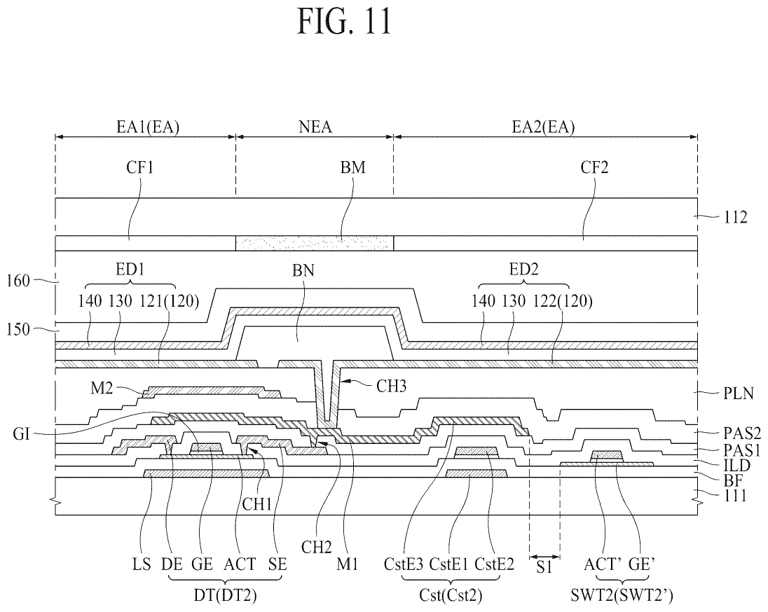

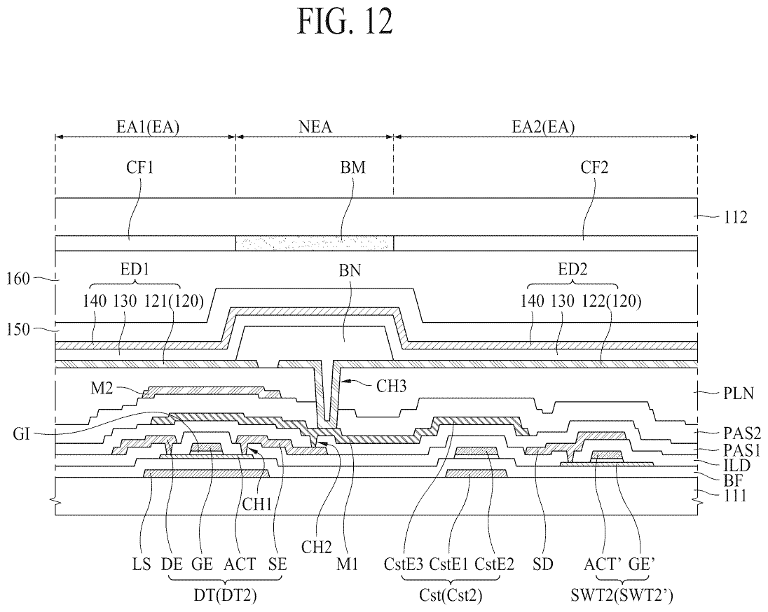

FIG. 11 schematically illustrates another example in which a first metal layer is disposed in a circuit area, and FIG. 12 schematically illustrates an example in which a shield layer is disposed in a circuit area.

A second circuit element CE2 corresponding to a second subpixel SP2 may include a second driving transistor DT2, a second capacitor Cst2, and at least one second switching transistor SWT2 and SWT2′. The second driving transistor DT2 of the second subpixel SP2 may at least partially overlap a first light emitting element ED1 of a first subpixel SP1, and the second capacitor Cst2 and the at least one second switching transistor SWT2 and SWT2′ of the second subpixel SP2 may at least partially overlap a second light emitting element ED2 of the second subpixel SP2.

Referring to FIGS. 11 and 12, a first metal layer M1 may extend from the area where the first light emitting element ED1 of the first subpixel SP1 is disposed to the area where the second light emitting element ED2 of the second subpixel SP2 is disposed. In this case, the first metal layer M1 may extend to the area where the second capacitor Cst2 of the second subpixel SP2 is formed.

The first metal layer M1 may be disposed to overlap a gate electrode GE of the second driving transistor DT2 in the area where the first light emitting element ED1 of the first subpixel SP1 is disposed. In this case, the first metal layer M1 may remove a first parasitic capacitance C_DTG between the gate electrode GE of the second driving transistor DT2 and an anode electrode 121 of the first light emitting element ED1.

In addition, the first metal layer M1 may be disposed to overlap the second capacitor Cst2 in the area where the second light emitting element ED2 of the second subpixel SP2 is disposed. In this case, the first metal layer M1 may be one capacitor electrode CstE3 constituting the second capacitor Cst2 in the area overlapping the second capacitor Cst2.

The second capacitor Cst2 may include at least two capacitor electrodes. For example, the second capacitor Cst2 may include a first capacitor electrode CstE1, a second capacitor electrode CstE2, and a third capacitor electrode CstE3. The first capacitor electrode CstE1 may be formed of the same material on the same layer as a light shielding layer LS, and the second capacitor electrode CstE2 may be formed of the same material on the same layer as the gate electrode GE. The third capacitor electrode CstE3 may be formed of the same material on the same layer as the first metal layer M1. In an example, the first capacitor electrode CstE1 may be connected to the light shielding layer LS, the second capacitor electrode CstE2 may be connected to the gate electrode GE, and the third capacitor electrode CstE3 may be connected to the first metal layer M1.

In the display panel 110 according to an embodiment of the present disclosure, the third capacitor electrode CstE3 is formed by extending the first metal layer M1 to the area where the second light emitting element ED2 of the second subpixel SP2 is disposed so tat it is possible to improve the capacity of the second capacitor Cst2 in the limited space.

In addition, the display panel 110 according to an exemplary embodiment of the present disclosure may simultaneously form the first metal layer M1 and the third capacitor electrode CstE3 which remove the first parasitic capacitance C_DTG through a simple process. Accordingly, the display panel 110 according to an embodiment of the present disclosure may implement process optimization and may reduce production energy.

In addition, the first metal layer M1 may be disposed not to overlap at least the second switching transistor SWT2 and SWT2′ in the area where the second light emitting element ED2 of the second subpixel SP2 is disposed. As shown in FIG. 11, the first metal layer M1 may be spaced apart from at least one second switching transistor SWT2 and SWT2′ by a predetermined distance S1 in a plan view.

As described above, the first metal layer M1 may be electrically connected to a source electrode SE or drain electrode DE of the second driving transistor DT2. Accordingly, when the first metal layer M1 overlaps the second switching transistor SWT2 and SWT2′, the second switching transistor SWT2 and SWT2′ may be affected by a signal applied to the source electrode SE or drain electrode DE of the second driving transistor DT2. A characteristic abnormality of the second switching transistor SWT2 and SWT2′ may occur. When the second subpixel SP2 is driven with black, black lifting defects in which luminance increases may occur.

In the display panel 110 according to an embodiment of the present disclosure, the first metal layer M1 is disposed apart from at least one second switching transistor SWT2 and SWT2′ so that it is possible to prevent or reduce the signal applied to the source electrode SE or drain electrode DE of the second driving transistor DT2 from affecting at least one second switching transistor SWT2 and SWT2′. Accordingly, the display panel 110 according to an embodiment of the present disclosure may prevent or reduce the occurrence of black lifting defects.

As shown in FIG. 12, the display panel 110 according to an embodiment of the present disclosure may further include a shield layer SD provided on at least one second switching transistor SWT2 and SWT2′ so that it is possible to completely prevent or reduce the signal applied to the source electrode SE or drain electrode DE of the second driving transistor DT2 from affecting at least one second switching transistor SWT2 and SWT2′. The shield layer SD may be provided on the same layer as the source electrode SE or the drain electrode DE of the second driving transistor DT2. The shield layer SD may be connected to a source region or a drain region of an active layer ACT of the at least one second switching transistor SWT2 and SWT2′ through a fourth contact hole CH4 penetrating through an interlayer insulating layer ILD.

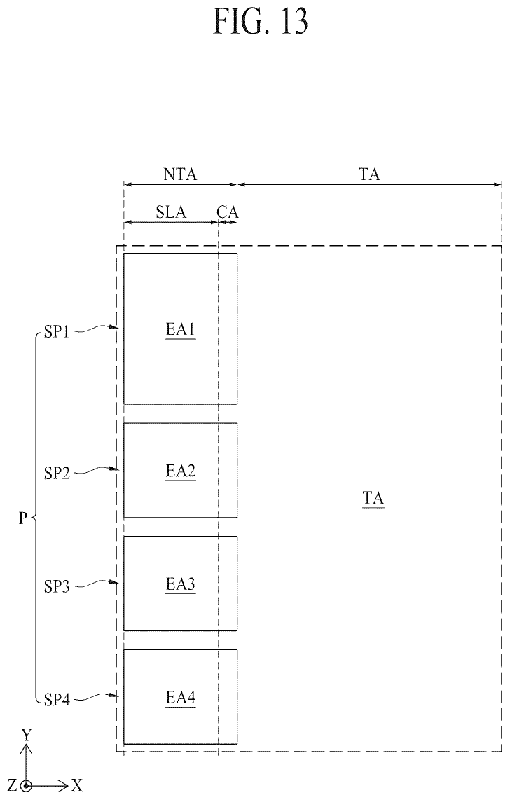

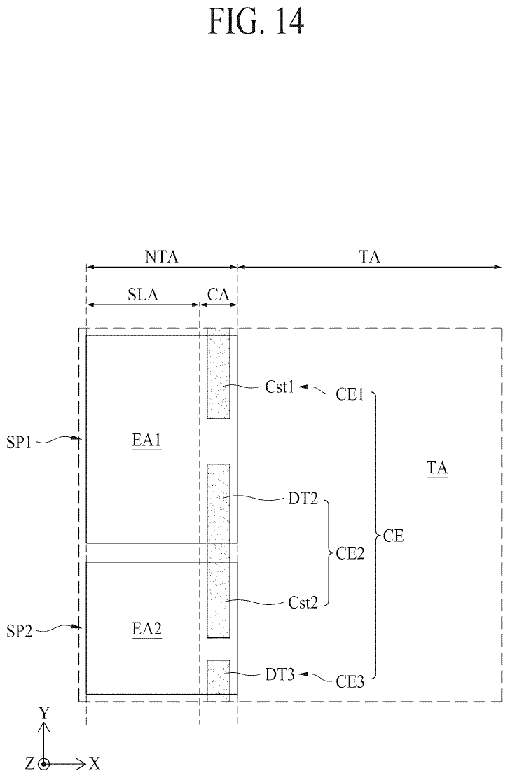

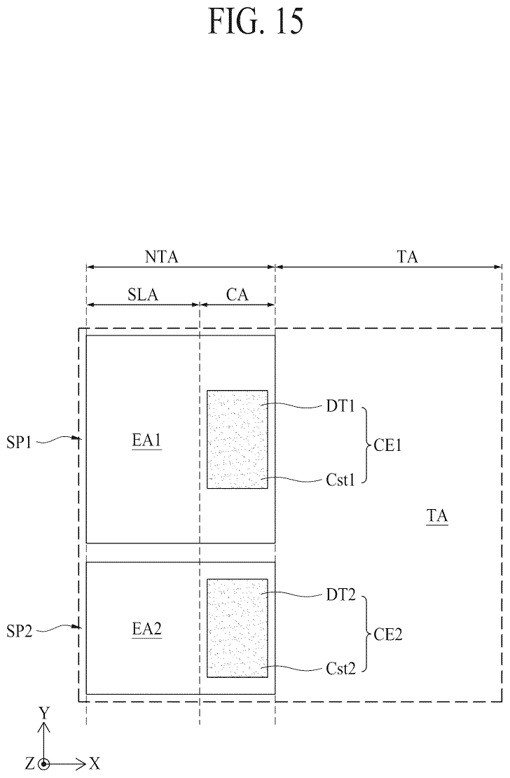

FIG. 13 schematically illustrates another embodiment of a pixel provided in a region A of FIG. 2, and FIG. 14 schematically illustrates an example in which a pixel circuit is disposed in a circuit area of FIG. 13. FIG. 15 schematically illustrates an example in which a transmission area is reduced in size according to a pixel circuit arrangement.

The display panel 110 shown in FIGS. 13 and 14 is different from the display panel 110 shown in FIGS. 3 to 12 in that a transmission area TA is provided. Hereinafter, differences will be mainly described, and substantially the same contents may be omitted or briefly provided.

The display panel 110 according to another embodiment of the present disclosure may include a display area DA and a non-display area NDA (See FIG. 2). As shown in FIG. 13, the display area DA may include a first area NTA in which a plurality of subpixels SP1, SP2, SP3, and SP4 are disposed, and a second area TA in which a plurality of subpixels SP1, SP2, SP3, and SP4 are not disposed. The first area NTA may be a non-transmission area which does not transmit most of the light incident from the outside. The second area TA may be a transmission area through which most of light incident from the outside passes. For example, the transmission area TA may be an area in which the light transmittance is greater than α%, and the non-transmission area NTA may be an area in which the light transmittance is less than β%. Herein, ‘α’ may be a value greater than ‘β’. The display panel 110 according to another embodiment of the present disclosure may view an object or a background located on a rear surface (or back surface) of the display panel 110 through transmission areas TA.

The non-transmission area NTA may include emission areas EA1, EA2, EA3, and EA4 provided with a plurality of pixels P to emit light, and a non-emission area provided between each of the emission areas. Each pixel P may include at least two subpixels SP. For example, each pixel P may include a first subpixel SP1 which emits red light, a second subpixel SP2 which emits green light, and a third subpixel SP3 which emits blue light, but not limited thereto. Each pixel P may further include a fourth subpixel SP4 which emits white light.

The non-transmission area NTA may include a signal line area SLA in which a plurality of signal lines DL, VDDL, VSSL, and REFL (See FIG. 4) are disposed, and a circuit area CA in which circuit elements DT, SWT, SWT′, and Cst (See FIG. 4) are disposed. In this case, the plurality of signal lines disposed in the signal line area SLA may include signal lines extending in the second direction (e.g., Y-axis direction).

In the display panel 110 according to another embodiment of the present disclosure, since the transmission area TA is provided in the display area DA, the area of the non-transmission area NTA that includes the emission areas EA1, EA2, EA3, and EA4 is reduced. Since the display panel 110 according to another embodiment of the present disclosure needs to include the plurality of light emitting elements, the plurality of signal lines, and the plurality of circuit elements in the narrow non-transmission area NTA, the plurality of light emitting elements may be formed to overlap the plurality of signal lines and the plurality of circuit elements. Accordingly, the display panel 110 according to another embodiment of the present disclosure may be disposed such that the signal line area SLA in which the plurality of signal lines DL, VDDL, VSSL, and REFL are disposed, and the circuit area CA in which the circuit elements DT, SWT, SWT′, and Cst are disposed may overlap the emission areas EA1, EA2, EA3, and EA4.

In addition, the display panel 110 according to another embodiment of the present disclosure may arrange the signal line area SLA and the circuit area CA so as not to overlap each other. When the circuit elements CE1, CE2, and CE3 are disposed between the plurality of signal lines DL, VDDL, VSSL, and REFL, the circuit elements CE1, CE2, and CE3 may need a space for securing a minimum separation distance from the plurality of signal lines DL, VDDL, VSSL, and REFL on the upper, lower, left, and right sides. Accordingly, the area in which the plurality of signal lines DL, VDDL, VSSL, and REFL and the circuit elements CE1, CE2, and CE3 are formed may increase.

In the display panel 110 according to another embodiment of the present disclosure, the circuit elements CE1, CE2, and CE3 may be gathered and disposed at one side of the signal line area SLA, thereby minimizing or at least reducing a space for separating the circuit elements CE1, CE2, and CE3 and the plurality of signal lines DL, VDDL, VSSL, and REFL.

In the display panel 110 according to another embodiment of the present disclosure, the circuit elements CE1, CE2, and CE3 corresponding to the plurality of subpixels SP1, SP2, SP3, and SP4 may be disposed in the second direction (e.g., Y-axis direction) along one edge area of each of the plurality of subpixels SP1, SP2, SP3, and SP4. In the display panel 110 according to another embodiment of the present disclosure, some area of the circuit elements CE1, CE2, and CE3 may be disposed to overlap the corresponding subpixels SP1, SP2, SP3, and SP4, and the other area of the circuit elements CE1, CE2, and CE3 may be disposed to overlap the adjacent subpixels SP1, SP2, SP3, and SP4.

For example, as shown in FIG. 14, a portion of the second circuit element CE2 corresponding to the second subpixel SP2 may overlap the second subpixel SP2, however, another portion of the second circuit element CE2 may not overlap the second subpixel SP2 and may overlap the adjacent first subpixel SP1. For example, the second capacitor Cst2 of the second circuit element CE2 overlaps the second subpixel SP2, however, the second driving transistor DT2 of the second circuit element CE2 may overlap the first subpixel SP1.

Accordingly, the display panel 110 according to another embodiment of the present disclosure may minimize or at least reduce the area of the circuit area CA. As shown in FIG. 15, the display panel 110 may be disposed such that all the circuit elements CE1, CE2, and CE3 are overlapped with corresponding subpixels SP1, SP2, SP3, and SP4. The first circuit element CE1 for driving the first subpixel SP1 may include a first driving transistor DT1, a first capacitor Cst1, and at least one first switching transistor SWT1 and SWT1′ (See FIG. 4). The first driving transistor DT1, the first capacitor Cst1, and the at least one first switching transistor SWT1 and SWT1′ (See FIG. 4) included in the first circuit element CE1 may be disposed at one edge area of the first subpixel SP1 and may overlap the first light emitting element of the first subpixel SP1. Also, the second circuit element CE2 for driving the second subpixel SP2 may include a second driving transistor DT2, a second capacitor Cst2, and at least one second switching transistor SWT2 and SWT2′ (See FIG. 4). The second driving transistor DT2, the second capacitor Cst2, and the at least one second switching transistor SWT2 and SWT2′ (See FIG. 4) included in the second circuit element CE2 may be disposed at one edge area of the second subpixel SP2 and may overlap the second light emitting element of the second subpixel SP2.

In this case, the first subpixel SP1 and the second subpixel SP2 need to secure a minimum area required for arranging the first circuit element CE1 and the second circuit element CE2 at one side area. Accordingly, there is a limitation in reducing the area of each of the first subpixel SP1 and the second subpixel SP2.

The display panel 110 according to another embodiment of the present disclosure may reduce the circuit area CA and may increase the transmission area TA in the pixel arrangement shown in FIG. 15. In the display panel 110 according to another embodiment of the present disclosure, the circuit elements CE1, CE2, and CE3 may be disposed in the circuit area CA secured at minimum. In this case, some of the circuit elements CE1, CE2, and CE3 may not be disposed in the area where the corresponding subpixels SP1, SP2, SP3, and SP4 are formed, and some of the circuit elements CE1, CE2, and CE3 may overlap the area where the subpixels SP1, SP2, SP3, and SP4 are formed.

The subpixels SP1, SP2, SP3, and SP4 may have different areas. Each of the subpixels SP1, SP2, SP3, and SP4 may have the different lifespan depending on a material of an emission layer for emitting light. In this case, the emission areas of the subpixels SP1, SP2, SP3, and SP4 may be designed to be the same as or different from each other so that the subpixels SP1, SP2, SP3, and SP4 may have the same or substantially similar lifespan.

At least one of the subpixels SP1, SP2, SP3, and SP4 may have the relatively large or small area compared to other subpixels. The circuit elements CE1, CE2, and CE3 corresponding to the subpixels SP1, SP2, SP3, and SP4 having the relatively small area may be formed such that at least a portion thereof overlaps the adjacent subpixels SP1, SP2, SP3, and SP4 when there is a free space in the adjacent subpixels SP1, SP2, SP3, and SP4.

For example, as shown in FIG. 14, the second subpixel SP2 may have an area smaller than that of the first subpixel SP1. A portion of the second circuit element CE2 corresponding to the second subpixel SP2 may overlap the second subpixel SP2, and another portion of the second circuit element CE2 may overlap the adjacent first subpixel SP1. For example, the second capacitor Cst2 of the second circuit element CE2 may overlap the second subpixel SP2, and the second driving transistor DT2 of the second circuit element CE2 may overlap the first subpixel SP1.

The display panel 110 according to another embodiment of the present disclosure may reduce the size of the circuit area CA and may increase the size of the transmission area TA. The display panel 110 according to another embodiment of the present disclosure may improve light transmittance.

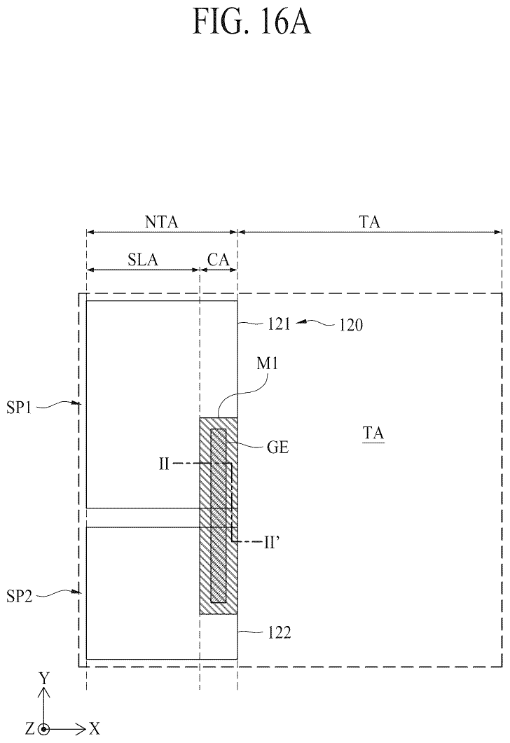

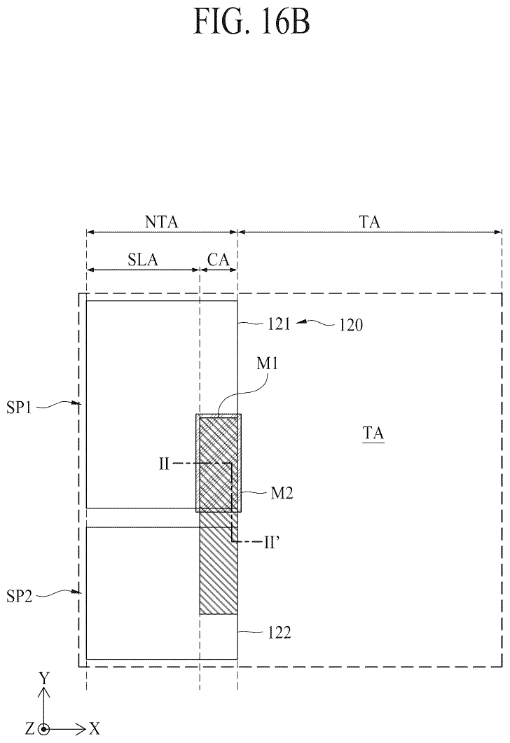

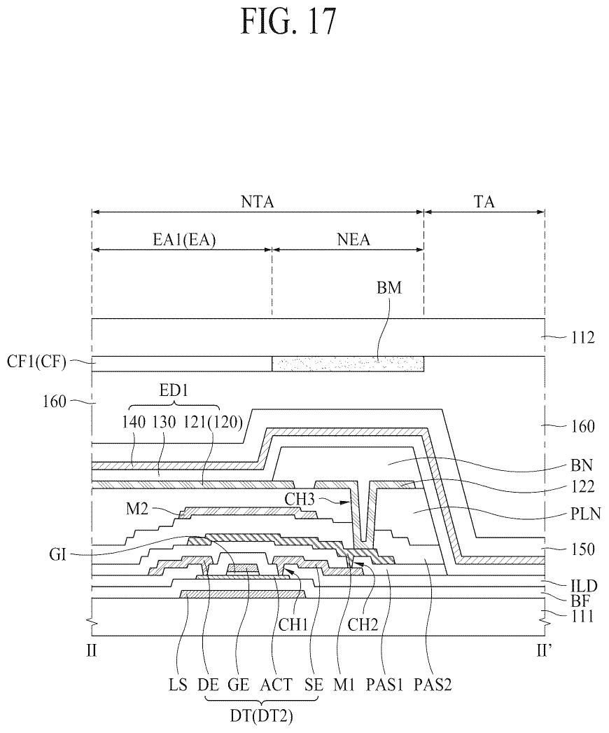

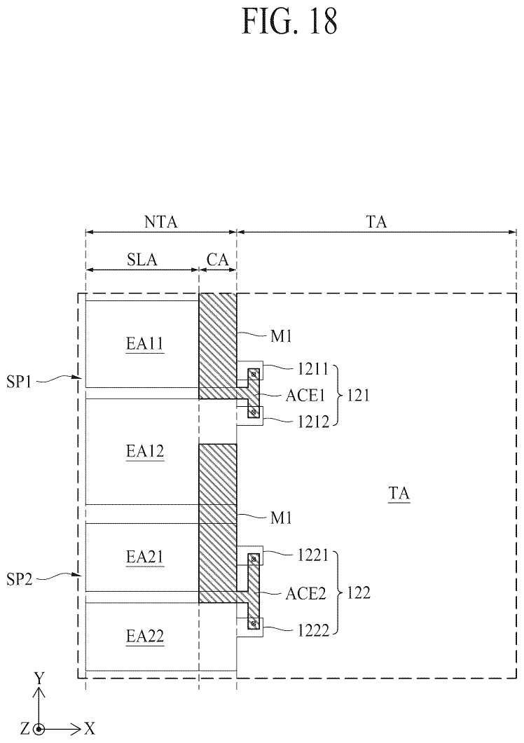

FIG. 16A schematically illustrates an example in which a first metal layer is disposed in a circuit area of FIG. 13, FIG. 16B schematically illustrates an example in which a second metal layer is disposed in a circuit area of FIG. 13, and FIG. 17 is a cross-sectional view illustrating an embodiment along II-II′ of FIGS. 16A and 16B. FIG. 18 schematically illustrates another example in which a first metal layer is disposed in a circuit area of FIG. 13.

The display panel 110 shown in FIGS. 16A, 16B, and 17 is different from the display panel 110 shown in FIGS. 3 to 12 in that a transmission area TA is provided. Hereinafter, differences will be mainly described, and substantially the same contents may be omitted or briefly provided.

In FIGS. 16A, 16B, and 17, for convenience of description, a portion of the second circuit element CE2 connected to the second subpixel SP2 overlaps the first subpixel SP1, but not limited thereto. The following description may be applied to all cases in which a portion of the pixel circuit connected to one subpixel overlaps another neighboring subpixel.

Referring to FIGS. 16A, 16B, and 17, the second subpixel SP2 may include a second circuit element CE2 including a second driving transistor DT2 and a second capacitor Cst2. The second driving transistor DT2 of the second subpixel SP2 may at least partially overlap a first light emitting element ED1 of the neighboring first subpixel SP1.

A light shielding layer LS may be provided on a first substrate 111. The light shielding layer LS may be provided in an area where a driving transistor DT is formed in a non-transmission area NTA to block external light incident on an active layer ACT of the driving transistor DT.

A buffer layer BF may be disposed on the light shielding layer LS. The buffer layer BF may protect the driving transistor DT from impurities such as hydrogen or moisture penetrating through the first substrate 111 vulnerable to moisture permeation. As shown in FIG. 17, the buffer layer BF may be provided in the non-transmission area NTA and the transmission area TA, but not limited thereto. In another embodiment, the buffer layer BF may be provided only in the non-transmission are NTA and may not be provided in the transmission area TA.

The driving transistor DT may be disposed on the buffer layer BF. The driving transistor DT may include an active layer ACT, a gate electrode GE, a source electrode SE, and a drain electrode DE disposed on the buffer layer BF in the non-transmission area NTA.

A gate insulating layer GI may be provided between the active layer ACT and the gate electrode GE. An interlayer insulating layer ILD may be disposed between the gate electrode GE and the source electrode SE/the drain electrode DE.

A first insulating layer PAS1 may be provided on the driving transistor DT, and a second insulating layer PAS2 may be provided on the first insulating layer PAS1. The first insulating layer PAS1 and the second insulating layer PAS2 may be provided in the non-transmission area NTA and may not be provided in at least a portion of the transmission area TA. For example, the first insulating layer PAS1 and the second insulating layer PAS2 may include an opening region overlapping at least a portion of the transmission area TA. The first insulating layer PAS1 and the second insulating layer PAS2 may cause light refraction while light is transmitted, thereby lowering transparency. Accordingly, the display panel 110 according to another embodiment of the present disclosure may increase transparency by removing portions of the first insulating layer PAS1 and the second insulating layer PAS2 from the transmission area TA.

A first metal layer M1 may be provided between the first insulating layer PAS1 and the second insulating layer PAS2. The first metal layer M1 may be disposed on the driving transistor DT in the non-transmission area NTA. The first metal layer M1 may be provided to cover the gate electrode GE of the driving transistor D in a plan view. The first metal layer M1 may be electrically connected to one of the source electrode SE and the drain electrode DE of the driving transistor DT.

A planarization layer PLN for planarizing a step difference by the driving transistor DT may be provided on the second insulating layer PAS2. The planarization layer PLN may be provided in the non-transmission area NTA and may not be provided in at least a portion of the transmission area TA. For example, the planarization layer PLN may include an opening region overlapping at least a portion of the transmission area TA. The planarization layer PLN may cause light refraction while light is transmitted, thereby lowering transparency. Accordingly, the display panel 110 according to another embodiment of the present disclosure may increase transparency by removing a portion of the planarization layer PLN in the transmission area TA.

A second metal layer M2 may be provided between the second insulating layer PAS2 and the planarization layer PLN. The second metal layer M2 may be disposed on the first metal layer M1 in the non-transmission area NTA. The second metal layer M2 may be provided to cover a portion of the first metal layer M1 in a plan view. The second metal layer M2 may be provided to cover the area where the first metal layer M1 overlaps the first subpixel SP1. The second metal layer M2 may be in a floating state in which no layer is electrically connected.

The light emitting element ED including a first electrode 120, an emission layer 130, and a second electrode 140 and a bank BN may be provided on the planarization layer PLN.

The first electrode 120 may be disposed on the planarization layer PLN in the non-transmission area NTA and may be provided for each of the subpixels SP1, SP2, and SP3. The first electrode 120 may be electrically connected to one of the source electrode SE and the drain electrode DE of the driving transistor DT through the first metal layer M1. The first electrode 120 may be an anode electrode of the light emitting element ED.

The bank BN may be provided on the planarization layer PLN in the non-transmission area NTA. The bank BN may be formed to cover the edge of each of the first electrodes 120 and to expose a portion of each of the first electrodes 120.

The bank BN may be provided in the non-transmission area NTA and may not be provided in at least a portion of the transmission area TA. For example, the bank BN may include an opening region overlapping at least a portion of the transmission area TA. The bank BN may cause light refraction while light is transmitted therethrough, to thereby lower transparency. Accordingly, the display panel 110 according to another embodiment of the present disclosure may increase transparency by removing a portion of the bank BN from the transmission area TA.

The emission layer 130 may be provided on the first electrode 120. The emission layer 130 may include a hole transporting layer, an emission material layer, and an electron transporting layer.

In an embodiment, the emission layer 130 may be a common layer commonly formed in the subpixels SP1, SP2, SP3, and SP4. In this case, the emission layer 130 may be a white light emitting layer which emits white light. In this case, the emission layer 130 may be formed in the non-emission area NEA between the subpixels SP1, SP2, SP3, and SP4 as well as the subpixels SP1, SP2, SP3, and SP4. The emission layer 130 may be formed in the subpixels SP1, SP2, SP3, and SP4 and may be continuously formed between the subpixels SP1, SP2, SP3, and SP4. In addition, the emission layer 130 may be provided not only in the non-transmission area NTA including the emission areas EA1, EA2, EA3, and EA4 and the non-emission area NEA but also in the transmission area TA, but not limited thereto. The emission layer 130 may be patterned only in the non-transmission area NTA including the emission area EA1, EA2, EA3, and EA4 and the non-emission area NEA.

In another embodiment, the emission layer 130 may be provided by forming the emission material layer for each of the subpixels SP1, SP2, SP3, and SP4. For example, a red emission layer for emitting red light may be formed in the first subpixel SP1, a green emission layer for emitting green light may be formed in the second subpixel SP2, and a blue emission layer for emitting blue light may be formed in the third subpixel SP3. In this case, the emission material layer of the emission layer 130 may not be formed in the transmission area TA. However, except the emission material layer, a hole injection layer HIL, a hole transport layer HTL, an electron transport layer ETL, and an electron injection layer EIL may be commonly formed in the subpixels SP1, SP2, SP3, and SP4, and may also be formed in the transmission area TA.

The second electrode 140 may be provided on the emission layer 130. The second electrode 140 may be a common layer commonly formed in the subpixels SP1, SP2, SP3, and SP4. The second electrode 140 may be formed in the non-emission area NEA between the subpixels SP1, SP2, SP3, and SP4 as well as the emission areas EA1, EA2, EA3, and EA4 of the subpixels SP1, SP2, SP3, and SP4. The second electrode 140 may be formed in the subpixels SP1, SP2, SP3, and SP4 and may be continuously formed between the subpixels SP1, SP2, SP3, and SP4.

Also, the second electrode 140 may be provided not only in the non-transmission area NTA including the emission areas EA1, EA2, EA3, and EA4 and the non-emission area NEA but also in the transmission area TA, but not limited thereto. The second electrode 140 may be patterned only in the non-transmission area NTA including the emission area EA1, EA2, EA3, and EA4 and the non-emission area NEA.

An encapsulation layer 150 may be provided on the light emitting elements ED. The encapsulation layer 150 may be formed on the second electrode 140 and may be configured to cover the second electrode 140.

A color filter CF may be provided on one surface of a second substrate 112 confronting the first substrate 111. The color filter CF may be patterned for each of the subpixels SP1, SP2, SP3, and SP4.

A black matrix BM may be provided between the color filters CF provided in each of the subpixels SP1, SP2, SP3, and SP4. The black matrix BM may be provided between the subpixels SP1, SP2, SP3, and SP4, to thereby prevent or reduce color mixing between the adjacent subpixels SP1, SP2, SP3, and SP4. In addition, the black matrix BM may prevent or reduce light incident from the outside from being reflected to the plurality of signal lines provided between the subpixels SP1, SP2, SP3, and SP4.

In addition, the black matrix BM may be provided between the transmission area TA and the plurality of subpixels SP1, SP2, SP3, and SP4 and may prevent or reduce light emitted from each of the plurality of subpixels SP1, SP2, SP3, and SP4 from proceeding to the transmission area TA. Accordingly, the black matrix BM may define the boundary between the transmission area TA and the non-transmission area NTA. In detail, the black matrix BM may define the boundary between the non-transmission area NTA and the transmission area TA in the area between the emission area EA and the transmission area TA. In the area excluding the emission area EA, the area where the black matrix BM is formed may be the non-transmission area NT, and the area where the black matrix BM is not formed may be the transmission area TA. For example, the area where the emission area EA and the black matrix BM are formed may be the non-transmission area NTA, and the remaining area may be the transmission area TA.

A filler 160 may be provided between the first substrate 111 provided with the light emitting elements ED and the second substrate 112 provided with the color filter CF and the black matrix BM.

In the same manner as the display panel 110 shown in FIGS. 3 to 12, the display panel 110 according to another embodiment of the present disclosure may remove a first parasitic capacitance C_DTG which might occur between the gate electrode GE of the second driving transistor DT2 and the anode electrode 121 of the first light emitting element ED1 by using the first metal layer M1.

Specifically, in the display panel 110 according to another embodiment of the present disclosure, the first metal layer M1 may be disposed between the second driving transistor DT2 of the second subpixel SP2 and the first light emitting element ED1 of the first subpixel SP1. The first metal layer M1 may be disposed over at least one of the source electrode SE and the drain electrode DE of the second driving transistor DT2 and may be electrically connected to one of the source electrode SE and the drain electrode DE of the second driving transistor DT2. For example, as shown in FIG. 17, the first metal layer M1 may be disposed over the source electrode SE of the second driving transistor DT2 and may be electrically connected to the source electrode SE of the second driving transistor DT2 through a second contact hole CH2.

The first metal layer M1 may be disposed in the area where the second driving transistor DT2 of the second subpixel SP2 overlaps the first light emitting element ED1 of the first subpixel SP1. The first metal layer M1 may extend from the area overlapping the first light emitting element ED1 of the first subpixel SP1 to the area where the second light emitting element ED2 of the second subpixel SP2 is disposed, and may be electrically connected to the anode electrode 122 of the second light emitting element ED2. The anode electrode 122 of the second light emitting element ED2 may be electrically connected to the source electrode SE of the second driving transistor DT2 through the first metal layer M1. In this case, the first metal layer M1 may be referred to as a mediate electrode for connecting the source electrode SE of the second driving transistor DT2 with the anode electrode 122 of the second light emitting element ED2 so as to reduce the contact resistance therebetween.

The first metal layer M1 may be formed to cover the gate electrode GE of the second driving transistor DT2 in the area where the second driving transistor DT2 and the first light emitting element ED1 overlap each other in a plan view.

In the display panel 110 according to another embodiment of the present disclosure, the first metal layer M1 may be disposed between the gate electrode GE of the second driving transistor DT2 and the anode electrode 121 of the first light emitting element ED1, and the first metal layer M1 may be electrically connected to the source electrode SE or the drain electrode DE of the second driving transistor DT2 so that it is possible to remove the first parasitic capacitance C_DTG. Accordingly, even when the voltage is applied to the anode electrode 121 of the first light emitting element ED1, there may be no change in the voltage of the gate electrode GE of the second driving transistor DT2 in the display panel 110 according to another embodiment of the present disclosure.

In the same manner as the display panel 110 shown in FIGS. 3 to 12, the display panel 110 according to another embodiment of the present disclosure may arrange the second metal layer M2 disposed between the first metal layer M1 and the first light emitting element ED1 of the first subpixel SP1. The second metal layer M2 may be disposed in the area where the first metal layer M1 overlaps the first light emitting element ED1 of the first subpixel SP1. The second metal layer M2 may be provided to cover a portion of the first metal layer M1, which overlaps the first light emitting element ED1, in a plan view. The second metal layer M2 may be in a floating state in which no layer is electrically connected.

The display panel 110 according to another embodiment of the present disclosure may arrange the second metal layer M2 in a floating state between the first metal layer M1 and the anode electrode 121 of the first light emitting element ED1. In this case, the second metal layer M2 may overlap the second subpixel SP2 and may not overlap the first subpixel SP1. In addition, the second metal layer M2 may have a smaller formation area than the area in which the second driving transistor DT2 is disposed. The display panel 110 according to another embodiment of the present disclosure may reduce the second parasitic capacitance C_DTS by using the second metal layer M2.

Since the source electrode SE or the drain electrode DE of the second driving transistor DT2 is fixed to the driving voltage Vgs even during a period in which the scan signal Scan (See FIG. 4) is not applied, the first metal layer M1 may be less affected by the peripheral signal compared to the gate electrode GE in the floating state. When the voltage is applied to the anode electrode 121 of the first light emitting element ED1 disposed over the source electrode SE or the drain electrode DE, the voltage of the source electrode SE or the drain electrode DE of the second driving transistor DT2 connected to the first metal layer M1 may also increase by the second parasitic capacitance C_DTS. However, since the source electrode SE or the drain electrode DE of the second driving transistor DT2 is not in the floating state but in the state being applied with the driving voltage Vgs, the voltage variation rate of the source electrode S or the drain electrode DE may be small compared to the gate electrode GE. In the display panel 110 according to another embodiment of the present disclosure, even when the voltage is applied to the anode electrode 121 of the first light emitting element ED1, the voltage variation of the source electrode SE of the second driving transistor DT2 may be minimized or at least reduced.

In addition, when the floated second metal layer M2 is disposed between the first metal layer M1 and the anode electrode 121 of the first light emitting element ED1, a third parasitic capacitance may be generated between the first metal layer M1 and the second metal layer M2, and a fourth parasitic capacitance may be generated between the second metal layer M2 and the anode electrode 121 of the first light emitting element ED1. In this case, the third parasitic capacitance and the fourth parasitic capacitance may be connected in series. The second parasitic capacitance C_DTS obtained by synthesizing the third parasitic capacitance and the fourth parasitic capacitance connected in series may be represented as the reciprocal of value obtained by summing the reciprocal of the third parasitic capacitance and the reciprocal of the fourth parasitic capacitance. The second parasitic capacitance C_DTS obtained by synthesizing the third parasitic capacitance and the fourth parasitic capacitance connected in series when the second metal layer M2 is present may be smaller than the second parasitic capacitance C_DTS generated between the first metal layer M1 and the anode electrode 121 of the first light emitting element ED1 when the second metal layer M2 is not present. Therefore, the display panel 110 according to another embodiment of the present disclosure may reduce the second parasitic capacitance C_DTS by the use of the second metal layer M2.

The display panel 110 according to another embodiment of the present disclosure may prevent or reduce the luminance of the second subpixel SP2 from rising by the driving of the adjacent first subpixel SP1. The display panel 110 according to another embodiment of the present disclosure may improve a grayscale defect of the second subpixel SP2.

FIGS. 3 to 17 illustrate that one subpixel SP1, SP2, SP3, or SP4 includes one emission area EA1, EA2, EA3, or EA4, but the present disclosure is not limited thereto.

As shown in FIG. 18, each of the subpixels SP1, SP2, SP3, and SP4 may include a plurality of divided emission areas EA1, EA2, EA3, and EA4. For example, the first emission area EA1 included in the first subpixel SP1 may include a first divided emission area EA11 and a second divided emission area EA12 divided into two. The second emission area EA2 included in the second subpixel SP2 may include a first divided emission area EA21 and a second divided emission area EA22 divided into two. The third emission area EA3 included in the third subpixel SP3 may include a first divided emission area EA31 and a second divided emission area EA32 divided into two. The fourth emission area EA4 included in the fourth subpixel SP4 may include a first divided emission area EA41 and a second divided emission area EA42 divided into two.

In this case, a plurality of first electrodes 120 may be provided in each of the plurality of subpixels SP1, SP2, SP3, and SP4. The first electrode 120 may include a first anode electrode and a second anode electrode. The first anode electrode may be disposed in the first divided emission area EA11, EA21, EA31, and EA41, and the second anode electrode may be disposed in the second divided emission area EA12, EA22, EA32, and EA42. The first anode electrode and the second anode electrode may be spaced apart from each other in the same layer.

The first anode electrode and the second anode electrode may be electrically connected to each other through an anode connection electrode. One end of the anode connection electrode may be electrically connected to the first anode electrode and the other end of the anode connection electrode may be electrically connected to the second anode electrode, thereby electrically connecting the first anode electrode and the second anode electrode to each other.

For example, the first electrode 121 provided in the first subpixel SP1 may include a first anode electrode 1211 disposed in the first divided emission area EA11, a second anode electrode 1212 disposed in the second divided emission area EA12, and an anode connection electrode ACE1 electrically connecting the first anode electrode 1211 and the second anode electrode 1212 to each other. One end of the anode connection electrode ACE1 may be electrically connected to the first anode electrode 1211 and the other end of the anode connection electrode ACE1 may be electrically connected to the second anode electrode 1212, thereby electrically connecting the first anode electrode 1211 and the second anode electrode 1212 provided in the first subpixel SP1.

The first electrode 122 provided in the second subpixel SP2 may include a first anode electrode 1221 disposed in the first divided emission area EA21, a second anode electrode 1222 disposed in the second divided emission area EA22, and an anode connection electrode ACE2 electrically connecting the first anode electrode 1221 and the second anode electrode 1222.

The anode connection electrodes ACE1 and ACE2 provided in the respective first subpixel SP1 and second subpixel SP2 may be provided on the same layer as the first metal layer M1 and may be connected to the first metal layer M1. The anode connection electrode ACE1 provided in the first subpixel SP1 may be connected to the first metal layer M1 connected to the first driving transistor DT1, and the anode connection electrode ACE2 provided in the second subpixel SP2 may be connected to the first metal layer M1 connected to the second driving transistor DT2.

Referring to FIGS. 14, 16A, 17, and 18, the first metal layer M1 connected to the source electrode SE of the second driving transistor DT2 may extend from the area where the second driving transistor DT2 and the first light emitting element ED1 of the first subpixel SP1 overlap to the area where the second light emitting element ED2 of the second subpixel SP2 is disposed. The first metal layer M1 may extend to one side of the anode connection electrode ACE2 of the second subpixel SP2 and may be connected to the anode connection electrode ACE2 of the second subpixel SP2. The first metal layer M1 may be electrically connected to the first anode electrode 1221 and the second anode electrode 1222 of the second subpixel SP2 through the anode connection electrode ACE2.

It is to be noted that although the example embodiments with reference to FIGS. 5 to 18 are described in a case in which the driving transistor of one subpixel overlaps with the light emitting element of another adjacent subpixel, but the present disclosure is not limited thereto. For example, such parasitic capacitance may also occur when another element such as the capacitor or the switching transistor of one subpixel overlaps with the light emitting element of another adjacent subpixel (which may also cause the undesired increase or decrease in luminance of the subpixel). Accordingly, when another element such as the capacitor or the switching transistor of one subpixel overlaps with the light emitting element of another adjacent subpixel, the first metal layer or the second metal layer may also be similarly disposed as the embodiments shown in FIGS. 5 to 18 so as to remove or reduce such parasitic capacitance.

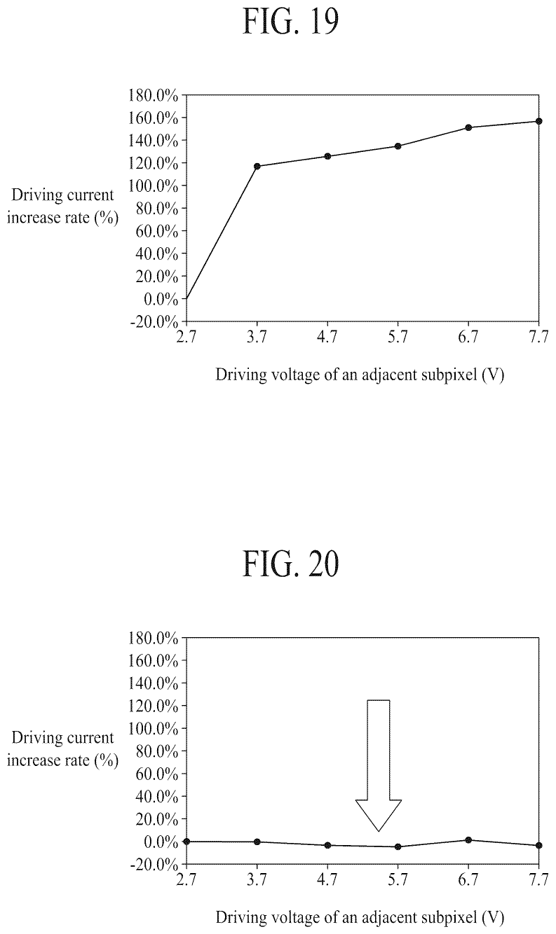

FIG. 19 is a graph showing a driving current increase rate according to a driving voltage of an adjacent subpixel when a first metal layer and a second metal layer are not provided, and FIG. 20 is a graph showing a driving current increase rate according to a driving voltage of an adjacent subpixel when a first metal layer and a second metal layer are provided.

The display panel 110 may be disposed such that a driving transistor of a specific subpixel overlaps a light emitting element of an adjacent subpixel. In this case, a parasitic capacitance may occur between the driving transistor of the specific subpixel and the light emitting element of the adjacent subpixel, particularly, an anode electrode.

A first parasitic capacitance may occur between a gate electrode of the driving transistor of the specific subpixel and the anode electrode of the adjacent subpixel. In addition, a second parasitic capacitance may occur between a source electrode of the driving transistor of the specific subpixel and the anode electrode of the adjacent subpixel.

In the driving transistor of the specific subpixel, as shown in FIG. 19, a driving current supplied to the anode electrode of the specific subpixel may increase by the first parasitic capacitance and the second parasitic capacitance when the adjacent subpixel is driven. Accordingly, as a luminance increases, the specific subpixel does not emit light with a desired luminance and a grayscale defect may occur.

As known from FIG. 19, as the driving voltage applied to the adjacent subpixel increases, a driving current increase rate for the specific subpixel may increase. Accordingly, as the driving voltage applied to the adjacent subpixel increases, a luminance increase rate of the specific subpixel increases, whereby it may be visible to eyes of a user.

On the other hand, the display panel 110 according to the present disclosure may remove the first parasitic capacitance by using the first metal layer and may reduce the second parasitic capacitance by using the second metal layer. Accordingly, in the display panel 110 according to the present disclosure, as shown in FIG. 20, the variation in the driving current supplied to the anode electrode of specific subpixel may be not large even when the adjacent subpixel is driven. For example, the grayscale defect for the subpixel may be not generated in the display panel 110 according to the present disclosure.

In the display panel 110 according to the present disclosure, as the product defect rate decreases, manufacturing process costs may be reduced, manufacturing process time may be shortened, and production energy may be reduced. In addition, the display panel 110 according to the present disclosure may reduce the generation of greenhouse gas which may occur due to the manufacturing process, thereby implementing ESG (Environment/Social/Governance).

In the present disclosure, the first metal layer is disposed between the gate electrode of the driving transistor of the specific subpixel and the anode electrode of the adjacent subpixel, thereby removing the first parasitic capacitance. Also, in the present disclosure, the second parasitic capacitance may be reduced by disposing the second metal layer in the floating state between the first metal layer and the anode electrode of the adjacent subpixel.

Also, in the present disclosure, even when the adjacent subpixels are driven, the variation in the driving current supplied to the anode electrode of the specific subpixel may not be significantly changed. For example, the present disclosure may prevent or reduce the grayscale defect with respect to the parasitic capacitance.

Also, in the present disclosure, a portion of the first metal layer may be used as the capacitor electrode, thereby increasing the capacitance of the capacitor. The present disclosure may improve the luminance of subpixel according to the increase in capacitance of the capacitor.

In addition, the present disclosure may simultaneously form the first metal layer and the capacitor electrode for removing the first parasitic capacitance through a simple process. Accordingly, the present disclosure may implement process optimization and may reduce production energy.

Also, the present disclosure may improve transparency by removing insulation layers from the transmission area.

In addition, in the present disclosure, as the product defect rate decreases, the manufacturing process cost may be reduced, the manufacturing process time may be shortened, and the production energy may be reduced. In addition, the present disclosure may reduce the generation of greenhouse gas which may occur due to the manufacturing process, thereby implementing ESG (Environment/Social/Governance).

Although the embodiments of the present disclosure have been described in more detail with reference to the accompanying drawings, the present disclosure is not necessarily limited to this embodiment and may be variously modified without departing from the spirit of the present disclosure. Therefore, the embodiments disclosed herein are intended to illustrate the scope of the technical idea of the present disclosure, and the scope of the technical idea of the present disclosure is not limited by the embodiments. Therefore, it should be understood that the embodiments described above are exemplary and not limiting in all respects.

What is claimed is:

1. A display device comprising:
a first subpixel and a second subpixel that are adjacent to each other;
a first light emitting element in the first subpixel;
a second light emitting element in the second subpixel;
a first driving transistor configured to supply a driving current to the first light emitting element;
a second driving transistor configured to supply a driving current to the second light emitting element, the second driving transistor at least partially overlapping the first light emitting element; and
a first metal layer between the second driving transistor and the first light emitting element.

2. The display device according to claim 1,
wherein the second driving transistor includes an active layer, a gate electrode, a source electrode, and a drain electrode, and
the first metal layer covers the gate electrode of the second driving transistor disposed in an area where the second driving transistor and the first light emitting element overlap each other in a plan view of the display device.

3. The display device according to claim 2,
wherein the first metal layer is on any one of the source electrode and the drain electrode.

4. The display device according to claim 2,
wherein the first metal layer is electrically connected to one of the source electrode and the drain electrode.

5. The display device according to claim 4,
wherein the first metal layer extends to an area in which the second light emitting element is disposed from an area where the second driving transistor and the first light emitting element overlap, and the first metal layer is electrically connected to an anode electrode of the second light emitting element.

6. The display device according to claim 1, further comprising a second metal layer between the first metal layer and the first light emitting element.

7. The display device according to claim 6, wherein the second metal layer is in a floating state.

8. The display device according to claim 6, wherein the second metal layer covers a portion of the first metal layer, that overlaps with the first light emitting element, in a plan view of the display device.

9. The display device according to claim 1, wherein the first subpixel and the second subpixel have different areas from each other.

10. The display device according to claim 1, wherein the second driving transistor is at one edge of the first subpixel.

11. The display device according to claim 1, further comprising:
a capacitor at one edge of the second subpixel.

12. The display device according to claim 11,
wherein the capacitor includes a first capacitor electrode and a second capacitor electrode,
the second driving transistor includes an active layer, a gate electrode, a source electrode, and a drain electrode, and
one of the first capacitor electrode and the second capacitor electrode is on a same layer as the gate electrode of the second driving transistor and connected to the gate electrode of the second driving transistor.

13. The display device according to claim 12, further comprising a light shielding layer disposed under the second driving transistor and electrically connected to one of the source electrode and the drain electrode of the second driving transistor and connected to the another one of the first capacitor electrode and the second capacitor.

14. The display device according to claim 11,
wherein the capacitor further includes a third capacitor electrode, and
the third capacitor electrode is on a same layer as the first metal layer and is connected to the first metal layer.

15. The display device according to claim 1,
wherein the second light emitting element includes an anode electrode, an emission layer, and a cathode electrode,
the anode electrode includes a first anode electrode, a second anode electrode, and an anode connection electrode electrically connecting the first anode electrode and the second anode electrode to each other, and
the anode connection electrode is on a same layer as the first metal layer.

16. The display device according to claim 15, wherein the first metal layer extends from an area where the second driving transistor and the first light emitting element overlap to an area where the second light emitting element is disposed and is connected to the anode connection electrode.

17. The display device according to claim 1, further comprising at least one switching transistor in an edge region of one side of the second subpixel.

18. The display device according to claim 17, wherein the first metal layer is spaced apart from the at least one switching transistor in a plan view of the display device.

19. The display device according to claim 17, further comprising a shield layer disposed on the at least one switching transistor.

20. A display device comprising:
a display area including a transmission area and a non-transmission area;
a first light emitting element and a second light emitting element that are adjacent to each other in the non-transmission area;
a first circuit element in the non-transmission area, the first circuit element configured to drive the first light emitting element; and
a second circuit element in the non-transmission area, the second circuit element configured to drive the second light emitting element,
wherein at least a portion of the second circuit element overlaps the first light emitting element.

21. The display device according to claim 20,
wherein the non-transmission area includes a signal line area in which a plurality of signal lines extending in a first direction are disposed, and
the first circuit element and the second circuit element are between the signal line area and the transmission area.

22. The display device according to claim 20, wherein the second circuit element includes a driving transistor in an area overlapping the first light emitting element and a capacitor in an area overlapping the second light emitting element.

23. The display device according to claim 22, further comprising:
a first metal layer between the driving transistor of the second circuit element and the first light emitting element.

24. The display device according to claim 23,
wherein the non-transmission area includes a signal line area in which a plurality of signal lines extending in a first direction are disposed, and
the first metal layer extends in the first direction between the signal line area and the transmission area.

25. The display device according to claim 23,
wherein the first metal layer extends from the area where the driving transistor of the second circuit element overlaps the first light emitting element to the area where the second light emitting element is disposed and is electrically connected to the second light emitting element.

26. The display device according to claim 23,
wherein the driving transistor of the second circuit element includes an active layer, a gate electrode, a source electrode, and a drain electrode, and
the first metal layer covers the gate electrode of the driving transistor in a plan view of the display device.

27. The display device according to claim 26, wherein the first metal layer is electrically connected to one of the source electrode and the drain electrode of the driving transistor.

28. The display device according to claim 23, further comprising:
a second metal layer between the first metal layer and the first light emitting element.

29. The display device according to claim 28,
wherein the non-transmission area includes a signal line area in which a plurality of signal lines extending in a first direction are disposed, and
the second metal layer is between the signal line area and the transmission area.

30. The display device according to claim 28, wherein the second metal layer is in a floating state.

31. The display device according to claim 28, further comprising:
a first insulating layer between the first metal layer and the driving transistor of the second circuit element;
a second insulating layer between the first metal layer and the second metal layer; and
a planarization layer between the second metal layer and the first light emitting element,
wherein the first insulating layer, the second insulating layer and the planarization layer are removed from the transmission area.

32. A display device comprising:
a first light emitting element and a second light emitting element disposed adjacent to each other;
a first circuit element configured to drive the first light emitting element;
a second circuit element configured to drive the second light emitting element and disposed to at least partially overlap the first light emitting element; and
a first metal layer disposed between the second circuit element and the first light emitting element.
